(19) United States
(12) Patent Application Publication
(10) Pub. No.: US 2024/0006437 A1
(43) Pub. Date: Jan. 4, 2024

(54) SOLID-STATE IMAGING DEVICE AND METHOD FOR MANUFACTURING SAME, AND ELECTRONIC INSTRUMENT

(71) Applicant: SONY SEMICONDUCTOR SOLUTIONS CORPORATION, KANAGAWA (JP)

(72) Inventors: YOSUKE NITTA, KANAGAWA (JP); NOBUTOSHI FUJII, KANAGAWA (JP); SUGURU SAITO, KANAGAWA (JP)

(21) Appl. No.: 18/252,839

(22) PCT Filed: Nov. 8, 2021
(86) PCT No.: PCT/JP2021/040907

§ 371 Date: May 12, 2023

(30) Foreign Application Priority Data
Nov. 20, 2020 (JP) 2020-193600

(51) Int. Cl. H01L 27/146; H01L 21/3205; H01L 23/528

(52) U.S. Cl. CPC H01L 27/14623; H01L 27/14636; H01L 21/3205; H01L 23/5283; H01L 27/14627

(57) ABSTRACT

While improving the bonding strength between a plurality of semiconductor substrates, the passage of noise from one of the plurality of semiconductor substrates to another is suppressed. A solid-state imaging device includes a first semiconductor substrate including a first semiconductor layer in which a photoelectric conversion unit is formed, and a first multilayer wiring layer including an interlayer insulating film, a second semiconductor substrate including a second semiconductor layer in which a circuit is formed and a second multilayer wiring layer including an interlayer insulating film, the second multilayer wiring layer being bonded to the first multilayer wiring layer, a light shielding layer provided in at least one of the first multilayer wiring layer or the second multilayer wiring layer so as to be exposed to a bonding surface between the first multilayer wiring layer and the second multilayer wiring layer, and an antioxidant layer provided in at least one of the first multilayer wiring layer or the second multilayer wiring layer and provided at least either between the light shielding layer and the interlayer insulating film of the first multilayer wiring layer or between the light shielding layer and the interlayer insulating film of the second multilayer wiring layer.

### TECHNICAL FIELD

The present technology (technology according to the present disclosure) relates to a solid-state imaging device and a method for manufacturing the same, and particularly relates to a technology of a solid-state imaging device including a plurality of semiconductor substrates bonded together.

### BACKGROUND ART

Recent examples of a method for manufacturing a three-dimensional integrated circuit or the like by bonding semiconductor substrates together include a method by which electrodes provided on bonding surfaces of semiconductor substrates are directly bonded together. For example, there is a method by which a first semiconductor substrate on which a light receiving element is formed and a second semiconductor substrate on which a peripheral circuit is formed are bonded together by an electrode such as Cu electrode (CuPad).

Furthermore, as disclosed in the following Patent Document 1, the examples of the method for manufacturing a three-dimensional integrated circuit or the like by bonding semiconductor substrates together include a method called atomic diffusion bonding by which a thin metal film is formed on a bonding surface of each semiconductor substrate, and the thin metal films are bonded together by being brought into contact with each other. Then, after the bonding, heat treatment is performed to convert a part of the thin metal films into an insulating film.

### CITATION LIST

### Patent Document

Patent Document 1: Japanese Patent Application Laid-Open No. 2013-168419

### SUMMARY OF THE INVENTION

### Problems to be Solved by the Invention

In a solid-state imaging device including a plurality of semiconductor substrates bonded together as described above, noise from one of the semiconductor substrates may affect an element such as a photoelectric conversion unit provided in the other semiconductor substrate. Furthermore, with the plurality of semiconductor substrates bonded together, the bonding strength is not sufficient in some cases.

It is therefore an object of the present technology to provide a solid-state imaging device, a method for manufacturing the same, and an electronic instrument capable of not only improving bonding strength between a plurality of semiconductor substrates but also suppressing passage of noise from one of the plurality of semiconductor substrates to the other semiconductor substrate.

### Solutions to Problems

A solid-state imaging device according to an aspect of the present technology includes: a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface; a second semiconductor substrate including a second semiconductor layer in which a circuit is formed and a second multilayer wiring layer including an interlayer insulating film formed on a side of the second semiconductor layer adjacent to the light incident surface, the second multilayer wiring layer being bonded to the first multilayer wiring layer; a light shielding layer provided in at least one of the first multilayer wiring layer or the second multilayer wiring layer so as to be exposed to a bonding surface between the first multilayer wiring layer and the second multilayer wiring layer; and an antioxidant layer provided in at least one of the first multilayer wiring layer or the second multilayer wiring layer and provided at least either between the light shielding layer and the interlayer insulating film of the first multilayer wiring layer or between the light shielding layer and the interlayer insulating film of the second multilayer wiring layer.

A solid-state imaging device according to another aspect of the present technology includes: a first wiring layer including a first wiring and a first interlayer insulating film and a second wiring layer including a second wiring and a second interlayer insulating film, the first wiring layer and the second wiring layer being arranged to cause a first surface of the first wiring layer and a second surface of the second wiring layer to face each other, the first surface including a first region, a second region, and a third region; a first insulating film provided in the first region, the first insulating film being different from the first interlayer insulating film; a first metal film provided in the second region, the first metal film being in contact with the first wiring; and a second metal film provided in the third region, the second metal film being in contact with a second insulating film different from the first insulating film and the first interlayer insulating film.

A method for manufacturing a solid-state imaging device according to another aspect of the present technology includes: preparing a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface, and a second semiconductor substrate including a second semiconductor layer in which a circuit is formed and a second multilayer wiring layer including an interlayer insulating film formed on a side of the second semiconductor layer adjacent to the light incident surface; forming an antioxidant layer in at least one of the interlayer insulating film of the first semiconductor substrate or the interlayer insulating film of the second semiconductor substrate; forming a high melting point metal film on a surface of the first semiconductor substrate adjacent to the interlayer insulating film and a surface of the second semiconductor substrate adjacent to the interlayer insulating film; bonding the high melting point metal film of the first semiconductor substrate and the high melting point metal film of the second semiconductor substrate to bond the first semiconductor substrate and the second semiconductor substrate together; and performing heat treatment on the first semiconductor substrate and the second semiconductor substrate bonded together.

An electronic instrument according to another aspect of the present technology includes: the solid-state imaging device; an optical lens configured to form an image of image light from a subject on an imaging surface of the solid-state imaging device; and a signal processing circuit configured to perform signal processing on a signal output from the solid-state imaging device.

### BRIEF DESCRIPTION OF DRAWINGS

FIG. 1 is a block diagram illustrating a configuration example of a solid-state imaging device according to the present technology.

FIG. 2A is a diagram schematically illustrating an example of a stacked structure of the solid-state imaging device according to the present technology.

FIG. 2B is a diagram schematically illustrating an example of the stacked structure of the solid-state imaging device according to the present technology.

FIG. 2C is a diagram schematically illustrating an example of the stacked structure of the solid-state imaging device according to the present technology.

FIG. 3 is a configuration diagram schematically illustrating a main part of a solid-state imaging device according to a first embodiment of the present technology.

FIG. 4A is a schematic plan view of the solid-state imaging device according to the first embodiment of the present technology.

FIG. 4B is a schematic cross-sectional view of a main part of a cross-sectional structure taken along a line A-A in FIG. 3.

FIG. 5 is a configuration diagram schematically illustrating a main part of a first semiconductor substrate side according to the first embodiment of the present technology.

FIG. 6A is a process cross-sectional view of a method for manufacturing the main part of the first semiconductor substrate side of the solid-state imaging device according to the first embodiment of the present technology.

FIG. 6B is a process cross-sectional view subsequent to FIG. 6A.

FIG. 6C is a process cross-sectional view subsequent to FIG. 6B.

FIG. 6D is a process cross-sectional view subsequent to FIG. 6C.

FIG. 6E is a process cross-sectional view subsequent to FIG. 6D.

FIG. 6F is a process cross-sectional view subsequent to FIG. 6E.

FIG. 6G is a process cross-sectional view subsequent to FIG. 6F.

FIG. 6H is a process cross-sectional view subsequent to FIG. 6G.

FIG. 7 is a configuration diagram schematically illustrating a main part of a second semiconductor substrate side according to the first embodiment of the present technology.

FIG. 8A is a process cross-sectional view of a method for manufacturing the main part of the second semiconductor substrate side of the solid-state imaging device according to the first embodiment of the present technology.

FIG. 8B is a process cross-sectional view subsequent to FIG. 8A.

FIG. 8C is a process cross-sectional view subsequent to FIG. 8B.

FIG. 8D is a process cross-sectional view subsequent to FIG. 8C.

FIG. 8E is a process cross-sectional view subsequent to FIG. 8D.

FIG. 8F is a process cross-sectional view subsequent to FIG. 8E.

FIG. 8G is a process cross-sectional view subsequent to FIG. 8F.

FIG. 8H is a process cross-sectional view subsequent to FIG. 8G.

FIG. 9A is a process cross-sectional view of a method for manufacturing a bonding layer according to the first embodiment of the present technology.

FIG. 9B is a process cross-sectional view subsequent to FIG. 9A.

FIG. 10 is a diagram illustrating a comparative example of a light shielding layer.

FIG. 11 is a configuration diagram schematically illustrating a bonding portion between a first semiconductor substrate and a second semiconductor substrate according to a modification 1 of the first embodiment of the present technology.

FIG. 12A is a process cross-sectional view of a method for manufacturing a main part of the second semiconductor substrate side of a solid-state imaging device according to the modification 1 of the first embodiment of the present technology.

FIG. 12B is a process cross-sectional view subsequent to FIG. 12A.

FIG. 12C is a process cross-sectional view of a method for manufacturing a bonding layer according to the modification 1 of the first embodiment of the present technology.

FIG. 12D is a process cross-sectional view subsequent to FIG. 12C.

FIG. 13 is a configuration diagram schematically illustrating a bonding portion between a first semiconductor substrate and a second semiconductor substrate according to a modification 2 of the first embodiment of the present technology.

FIG. 14 is a process cross-sectional view of a method for manufacturing a bonding layer according to the modification 2 of the first embodiment of the present technology.

FIG. 15 is a configuration diagram schematically illustrating a bonding portion between a first semiconductor substrate and a second semiconductor substrate according to a modification 3 of the first embodiment of the present technology.

FIG. 16A is a process cross-sectional view of a method for manufacturing a main part of the second semiconductor substrate side of a solid-state imaging device according to the modification 3 of the first embodiment of the present technology.

FIG. 16B is a process cross-sectional view subsequent to FIG. 16A.

FIG. 16C is a process cross-sectional view subsequent to FIG. 16B.

FIG. 16D is a process cross-sectional view subsequent to FIG. 16C.

FIG. 16E is a process cross-sectional view of a method for manufacturing a bonding layer according to the modification 3 of the first embodiment of the present technology.

FIG. 16F is a process cross-sectional view subsequent to FIG. 16E.

FIG. 17 is a configuration diagram schematically illustrating a bonding portion between a first semiconductor substrate and a second semiconductor substrate according to a modification 4 of the first embodiment of the present technology.

FIG. 18A is a process cross-sectional view of a method for manufacturing a main part of the second semiconductor substrate side of a solid-state imaging device according to the modification 4 of the first embodiment of the present technology.

FIG. 18B is a process cross-sectional view subsequent to FIG. 18A.

FIG. 18C is a process cross-sectional view of a method for manufacturing a bonding layer according to the modification 4 of the first embodiment of the present technology.

FIG. 18D is a process cross-sectional view subsequent to FIG. 18C.

FIG. 19 is a configuration diagram schematically illustrating a bonding portion between a first semiconductor substrate and a second semiconductor substrate according to a second embodiment of the present technology.

FIG. 20 is a plan view of an antioxidant layer and a light shielding layer of a solid-state imaging device according to the second embodiment of the present technology.

FIG. 21A is a process cross-sectional view of a method for manufacturing a main part of the first semiconductor substrate side of the solid-state imaging device according to the second embodiment of the present technology.

FIG. 21B is a process cross-sectional view subsequent to FIG. 21A.

FIG. 21C is a process cross-sectional view subsequent to FIG. 21B.

FIG. 22A is a process cross-sectional view of a method for manufacturing a main part of the second semiconductor substrate side of the solid-state imaging device according to the second embodiment of the present technology.

FIG. 22B is a process cross-sectional view subsequent to FIG. 22A.

FIG. 22C is a process cross-sectional view subsequent to FIG. 22B.

FIG. 23A is a process cross-sectional view of a method for manufacturing a bonding layer according to the second embodiment of the present technology.

FIG. 23B is a process cross-sectional view subsequent to FIG. 23A.

FIG. 24 is a plan view of an antioxidant layer and a light shielding layer of a solid-state imaging device according to another example of the second embodiment of the present technology.

FIG. 25 is a plan view of an antioxidant layer and a light shielding layer of a solid-state imaging device according to another example of the second embodiment of the present technology.

FIG. 26 is a plan view of an antioxidant layer and a light shielding layer of a solid-state imaging device according to another example of the second embodiment of the present technology.

FIG. 27 is a configuration diagram schematically illustrating an electronic instrument according to a third embodiment of the present technology.

### MODE FOR CARRYING OUT THE INVENTION

### Embodiment

Preferred embodiments for implementing the present technology will be described below with reference to the drawings. Note that, embodiments hereinafter described each illustrate an example of a representative embodiment of the present technology, and the scope of the present technology is not narrowed by them.

In the following drawings, the same or similar parts are denoted by the same or similar reference numerals. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it is needless to say that the drawings include portions having different dimensional relationships and ratios.

Furthermore, the first to third embodiments described below each illustrate an example of a device and a method for embodying the technical idea of the present technology, and the technical idea of the present technology does not limit the material, shape, structure, arrangement, and the like of components to the following. Various modifications can be made to the technical idea of the present technology within the technical scope defined by the claims described in the claims.

Note that the description will be given in the following order.
1. Configuration Example of Solid-State Imaging Device
2. Example of Stacked Structure of Solid-State Imaging Device
3. First Embodiment
4. Modification 1 of First Embodiment
5. Modification 2 of First Embodiment
6. Modification 3 of First Embodiment
7. Modification 4 of First Embodiment
8. Second Embodiment
9. Third Embodiment

<Configuration Example of Solid-State Imaging Device>

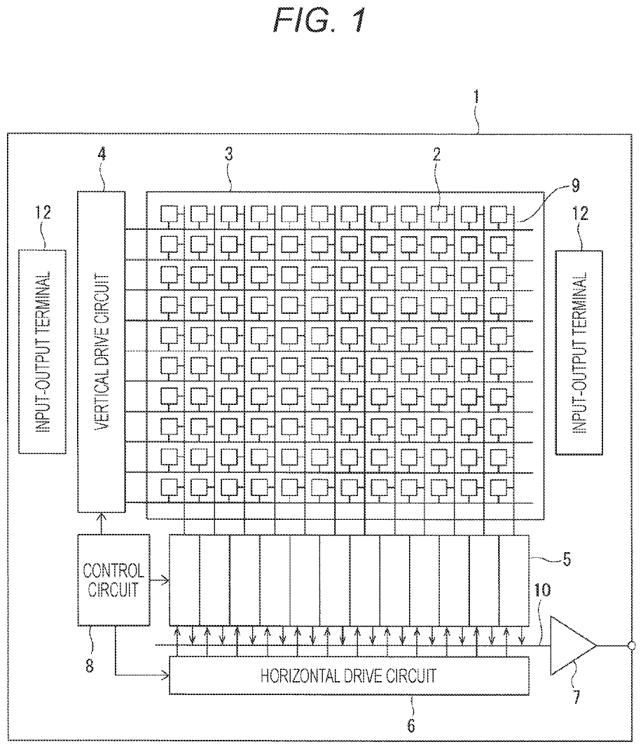

FIG. 1 is a block diagram illustrating a configuration example of a solid-state imaging device according to the present technology. As illustrated in FIG. 1, a solid-state imaging device 1 is configured as, for example, a complementary metal oxide semiconductor (CMOS) image sensor. The solid-state imaging device 1 includes a pixel region (pixel array) 3 in which a plurality of pixels 2 is regularly arranged in a two-dimensional array in a semiconductor substrate (for example, Si substrate) (not illustrated), and a peripheral circuit unit.

The pixel 2 includes a photoelectric conversion unit (for example, a photodiode) that performs photoelectric conversion, and a plurality of pixel transistors (MOS transistors). The plurality of pixel transistors may include three transistors, for example, a transfer transistor, a reset transistor, and an amplification transistor. Alternatively, the plurality of pixel transistors may include four transistors with a selection transistor added to them. Note that an equivalent circuit of the unit pixel is similar to an equivalent circuit according to a known technology, and thus no detailed description will be given of the equivalent circuit.

Furthermore, the pixel 2 may be configured as one unit pixel or may have a pixel sharing structure. This pixel sharing structure is a structure in which a plurality of photodiodes shares a floating diffusion and transistors other than a plurality of transfer transistors. That is, in the sharing pixel, the photodiodes and the transfer transistors constituting the plurality of unit pixels are configured to share another each pixel transistor.

The peripheral circuit unit includes a vertical drive circuit 4, a column signal processing circuit 5, a horizontal drive circuit 6, an output circuit 7, and a control circuit 8.

The vertical drive circuit 4 includes a shift register, for example. The vertical drive circuit 4 selects a pixel drive wiring, supplies a pulse for pixel driving to the selected pixel drive wiring, and drives pixels row by row. That is, the vertical drive circuit 4 selectively scans the pixels 2 of the pixel region 3 sequentially in a vertical direction row by row. Then, the vertical drive circuit 4 supplies a pixel signal based on a signal charge generated according to a light receiving amount in the photoelectric conversion unit of each pixel 2 to the column signal processing circuit 5 through a vertical signal line 9.

The column signal processing circuit 5 is arranged for each column of the pixels 2, for example. The column signal processing circuit 5 performs signal processing such as noise removal on the signals output from the pixels 2 of one row for each pixel column. Specifically, the column signal processing circuit 5 performs signal processing such as correlated double sampling (CDS) for removing fixed pattern noise unique to the pixels 2, signal amplification, and analog/digital (A/D) conversion. A horizontal selection switch (not illustrated) is provided at an output stage of the column signal processing circuit 5 and connected with a horizontal signal line 10.

The horizontal drive circuit 6 includes a shift register, for example. This horizontal drive circuit 6 sequentially selects each of the column signal processing circuits 5 by sequentially outputting horizontal scanning pulses, and causes each of the column signal processing circuits 5 to output a pixel signal to the horizontal signal line 10.

The output circuit 7 performs signal processing on signals sequentially supplied from each of the column signal processing circuits 5 through the horizontal signal line 10 and outputs processed signals. For example, the output circuit 7 may perform only buffering or may perform various types of digital signal processing such as black level adjustment or column variation correction.

The control circuit 8 receives an input clock and data giving a command of an operation mode and the like and outputs data of internal information and the like of the solid-state imaging device 1. Furthermore, the control circuit 8 generates a clock signal and a control signal which serve as a reference of operation of the vertical drive circuit 4, the column signal processing circuit 5, the horizontal drive circuit 6, and the like, on the basis of a vertical synchronization signal, a horizontal synchronization signal, and a master clock. Then, the control circuit 8 inputs these signals to the vertical drive circuit 4, the column signal processing circuit 5, the horizontal drive circuit 6, and the like.

An input-output terminal 12 exchanges signals with the outside.

<Example of Stacked Structure of Solid-State Imaging Device>

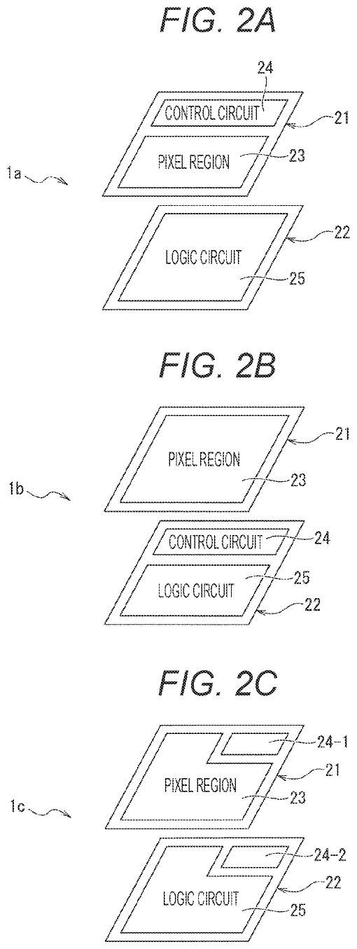

FIGS. 2A to 2C are diagrams schematically illustrating examples of a stacked structure of the solid-state imaging device according to the present technology. The examples of the stacked structure of the solid-state imaging device to which the present technology is applied will be described with reference to FIGS. 2A to 2C.

As a first example, a solid-state imaging device 1a illustrated in FIG. 2A includes a first semiconductor substrate 21 and a second semiconductor substrate 22. A pixel region 23 and a control circuit 24 are mounted on the first semiconductor substrate 21. A logic circuit 25 including a signal processing circuit is mounted on the second semiconductor substrate 22. Then, the first semiconductor substrate 21 and the second semiconductor substrate 22 are electrically connected to each other, thereby forming the solid-state imaging device 1a as one semiconductor chip.

As a second example, a solid-state imaging device 1b illustrated in FIG. 2B includes a first semiconductor substrate 21 and a second semiconductor substrate 22. A pixel region 23 is mounted on the first semiconductor substrate 21. A control circuit 24 and a logic circuit 25 including a signal processing circuit are mounted on the second semiconductor substrate 22. Then, the first semiconductor substrate 21 and the second semiconductor substrate 22 are electrically connected to each other, thereby forming the solid-state imaging device 1b as one semiconductor chip.

As a third example, a solid-state imaging device 1c illustrated in FIG. 2C includes a first semiconductor substrate 21 and a second semiconductor substrate 22. A pixel region 23 and a control circuit 24-1 that controls the pixel region 23 are mounted on the first semiconductor substrate 21. A control circuit 24-2 that controls a logic circuit 25 and the logic circuit 25 including a signal processing circuit are mounted on the second semiconductor substrate 22. Then, the first semiconductor substrate 21 and the second semiconductor substrate 22 are electrically connected to each other, thereby forming the solid-state imaging device 1c as one semiconductor chip.

Although not illustrated, depending on the configuration of the CMOS solid-state imaging device, two or more semiconductor substrates may be bonded together. For example, three or more semiconductor substrates including not only the first and second semiconductor substrates described above, but also a semiconductor substrate including a memory element array, a semiconductor substrate including other circuit elements, and the like may be bonded together to form a CMOS solid-state imaging device as one chip.

<Solid-State Imaging Device According to First Embodiment>

<Configuration Example of Solid-State Imaging Device>

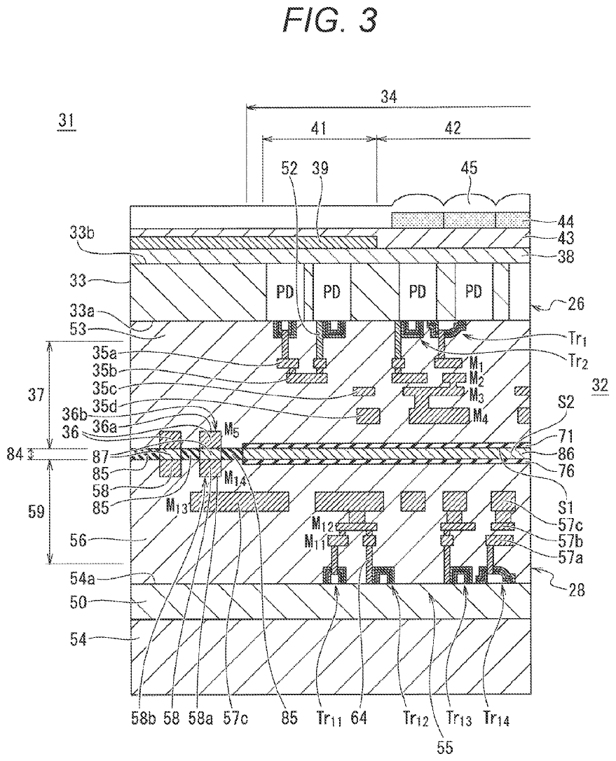

FIG. 3 illustrates a first embodiment of a solid-state imaging device according to the present technology, that is, a back-illuminated CMOS solid-state imaging device. The back-illuminated CMOS solid-state imaging device is a CMOS solid-state imaging device in which a light receiving unit is disposed above a circuit unit and which is higher in sensitivity and lower in noise than a front-illuminated CMOS solid-state imaging device. A solid-state imaging device 31 according to the first embodiment includes a stacked semiconductor chip 32 in which a first semiconductor substrate 26 in which a pixel region 23 and a control circuit 24 are formed and a second semiconductor substrate 28 in which a logic circuit 25 is formed are stacked and bonded together, as with the solid-state imaging device 1a in FIG. 2A. Here, the stacking direction of the first semiconductor substrate 26 and the second semiconductor substrate 28 is defined as a thickness direction of the solid-state imaging device 31.

[Configuration Example of First Semiconductor Substrate]

The first semiconductor substrate 26 includes a first semiconductor layer (semiconductor layer) 33 including thinned silicon and a multilayer wiring layer 37 (first multilayer wiring layer, first wiring layer) including an interlayer insulating film 53. The interlayer insulating film 53 formed in the multilayer wiring layer 37 may include a multilayer insulating film. In the first semiconductor layer 33, a pixel region 34 is formed in which a plurality of pixels including a photodiode PD serving as a photoelectric conversion unit and a plurality of pixel transistors Tr₁ and Tr₂ is two-dimensionally arranged in columns. That is, the first semiconductor substrate 26 includes the pixel region 34 in which a plurality of the photodiodes (photoelectric conversion units) PD is provided. Furthermore, although not illustrated, a plurality of MOS transistors constituting the control circuit 24 is formed in the first semiconductor layer 33. On a surface (principal surface) 33a of the first semiconductor layer 33, the multilayer wiring layer 37 in which a plurality of (in this example, five) layers of wirings 35 [35a to 35d] of metals M₁ to M₅ and a first connecting wiring 36 are arranged is formed via the interlayer insulating film 53. As the wirings 35 and the first connecting wiring 36, a copper (Cu) wiring formed by dual damascene is used. Note that a metal other than copper or an alloy of the metal may be used for the wirings 35 and the first connecting wiring 36.

Furthermore, a surface of first semiconductor layer 33 opposite from the surface 33a is a light incident surface 33b.

Here, a surface of the multilayer wiring layer 37 remote from the first semiconductor layer 33 is referred to as a surface S1 (first surface). Since the first semiconductor substrate 26 includes the multilayer wiring layer 37, the surface S1 also serves as a surface S1 of the first semiconductor substrate 26. The interlayer insulating film 53 includes a first uppermost interlayer insulating film 53c (first interlayer insulating film) facing the surface S1. The surface S1 is a surface of the first semiconductor substrate 26 adjacent to the first uppermost interlayer insulating film 53c.

The first uppermost interlayer insulating film 53c includes, for example, SiO₂, SiO, HfO, GeO, GaO, SiON, or the like. In the first embodiment, the first uppermost interlayer insulating film 53c includes SiO₂. For the interlayer insulating film 53 other than the first uppermost interlayer insulating film 53c, the same material as the first uppermost interlayer insulating film 53c or a material applied to an interlayer insulating layer of a known semiconductor device may be used.

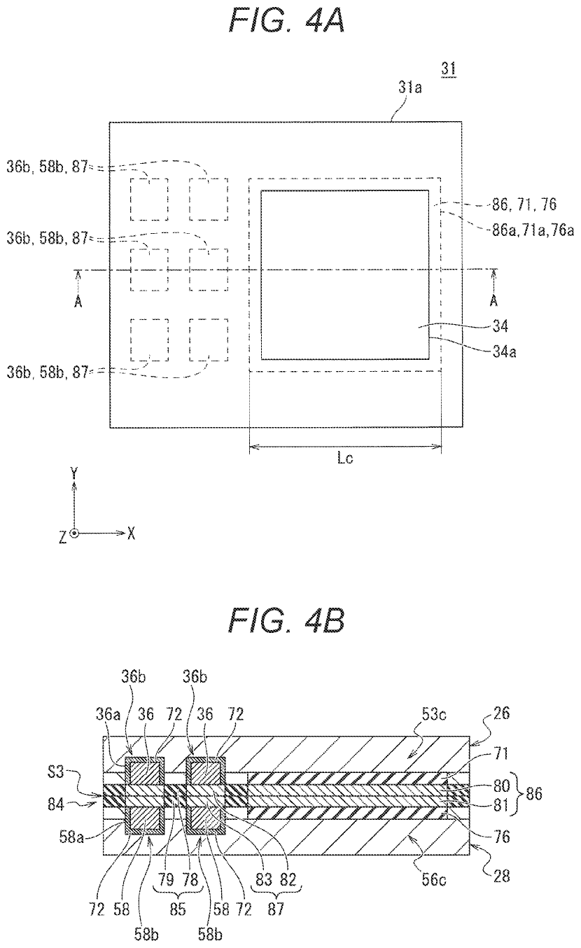

Then, the first uppermost interlayer insulating film 53c is provided with a first connecting pad 36b. FIG. 4B is a cross-sectional view illustrating a main part of a cross-sectional structure taken along a line A-A in FIG. 3, and is a schematic configuration diagram schematically illustrating a bonding portion between the first semiconductor substrate and the second semiconductor substrate. As illustrated in FIG. 4B, the first connecting pad 36b includes the first connecting wiring 36 and a Cu diffusion barrier metal film 72. As illustrated in FIG. 3, the first uppermost interlayer insulating film 53c is provided with a wiring groove 36a facing the surface S1, and the first connecting wiring 36 is embedded in the wiring groove 36a. As a result, the first connecting wiring 36 of the metal M₅ of the fifth layer is formed. Although not illustrated, the first connecting wiring 36 is connected to the wiring 35d of metal M₄ of the fourth layer and the like via a conductive via 52. As illustrated in FIG. 4B, the Cu diffusion barrier metal film is provided between the first connecting wiring 36 and the first uppermost interlayer insulating film 53c. As illustrated in FIG. 4B, the first connecting wiring 36 and the Cu diffusion barrier metal film 72 face the surface S1. That is, the first connecting pad 36b faces the surface S1. Examples of the Cu diffusion barrier metal film include Ta, TaN, Ti, TiN, W, WN, Ru, TiZrN, and alloy films containing these. Furthermore, the first connecting pad 36b and a wiring of metal of the same layer as the first connecting pad 36b are referred to as a first wiring in order to be distinguished from other wirings.

The first semiconductor substrate 26 further includes a first antioxidant layer 71 provided in the first uppermost interlayer insulating film 53c. A surface of the first antioxidant layer 71 remote from the first uppermost interlayer insulating film 53c faces the surface S1.

The first antioxidant layer 71 includes a substance (insulating film) that is lower in hygroscopicity than the interlayer insulating film 53. The first antioxidant layer 71 includes an insulating film that is lower in hygroscopicity than the first uppermost interlayer insulating film 53c. Examples of the first antioxidant layer 71 include silicon nitride (SiₓN_{y}), aluminum oxide (Al₂O₃), and the like. In the first embodiment, the first antioxidant layer 71 includes silicon nitride. Silicon nitride is lower in hygroscopicity than SiO₂.

The solid-state imaging device 31 further includes a light-receiving-side insulating film 38, a light-receiving-side light shielding film 39, a planarization film 43, a color filter 44, and an on-semiconductor chip lens 45.

On a back surface of the first semiconductor layer 33, the light-receiving-side light shielding film 39 is formed to cover an optical black region 41 with the light-receiving-side insulating film 38 interposed between the back surface and the light-receiving-side light shielding film 39, and the color filter 44 and the on-semiconductor chip lens 45 are formed on an effective pixel region 42 with the planarization film 43 further interposed between the back surface, and the color filter 44 and the on-semiconductor chip lens 45. The on-semiconductor chip lens 45 may also be formed on the optical black region 41.

FIG. 3 illustrates the pixel transistors Tr₁ and Tr₂ as representative of the plurality of pixel transistors. In the first semiconductor substrate 26, the photodiode PD is formed in the thinned first semiconductor layer 33. The photodiode PD is provided in the effective pixel region 42 and the optical black region 41 constituting the pixel region 34.

In the multilayer wiring layer 37 of the first semiconductor substrate 26, a pixel transistor and the wirings 35 corresponding to each other, and the wirings 35 of upper and lower layers adjacent to each other are connected via the conductive via 52.

[Configuration Example of Second Semiconductor Substrate]

The second semiconductor substrate 28 includes a second semiconductor layer (semiconductor layer) 54 including silicon and a multilayer wiring layer 59 (second multilayer wiring layer, second wiring layer) including an interlayer insulating film 56. The interlayer insulating film 56 formed in the multilayer wiring layer 59 may include a multilayer insulating film. The second semiconductor layer 54 includes a semiconductor well region 50. In a region of the second semiconductor layer 54 to be an individual semiconductor chip part, a logic circuit 55 constituting a peripheral circuit is formed. The logic circuit 55 includes a plurality of MOS transistors Tr₁₁ to Tr₁₄ including CMOS transistors. On a surface 54a (principal surface, surface adjacent to the light incident surface 33b, surface adjacent to the first semiconductor substrate 26) of the second semiconductor layer 54, the multilayer wiring layer 59 in which a plurality of (in this example, four) layers of wirings 57 [57a to 57c] of metals M₁₁ to M₁₄ and a second connecting wiring 58 are arranged is formed via the interlayer insulating film 56. As the wirings 57 and the second connecting wiring 58, a copper (Cu) wiring formed by dual damascene is used. Note that a metal other than copper or an alloy of the metal may be used for the wirings 57 and the second connecting wiring 58.

Here, a surface of the multilayer wiring layer 59 remote from the second semiconductor substrate 28 is referred to as a surface S2 (second surface). Since the second semiconductor substrate 28 includes the multilayer wiring layer 59, the surface S2 also serves as a surface S2 of the second semiconductor substrate 28. The interlayer insulating film 56 includes a second uppermost interlayer insulating film 56c (second interlayer insulating film) facing the surface S2. The surface S2 is a surface of the second semiconductor substrate 28 adjacent to the second uppermost interlayer insulating film 56c.

The second uppermost interlayer insulating film 56c includes, for example, SiO₂, SiO, HfO, GeO, GaO, SiON, or the like. In the first embodiment, the second uppermost interlayer insulating film 56c includes SiO₂. For the interlayer insulating film 53 other than the first uppermost interlayer insulating film 53c, the same material as the second uppermost interlayer insulating film 56c or a material applied to an interlayer insulating layer of a known semiconductor device may be used.

Then, the second uppermost interlayer insulating film 56c is provided with a second connecting pad 58b. As illustrated in FIG. 4B, the second connecting pad 58b includes the second connecting wiring 58 and a Cu diffusion barrier metal film 72. As illustrated in FIG. 3, the second uppermost interlayer insulating film 56c is provided with a wiring groove 58a facing the surface S2, and the second connecting wiring 58 is embedded in the wiring groove 58a. As a result, the second connecting wiring 58 of the metal M₁₄ of the fourth layer is formed. Although not illustrated, the second connecting wiring 58 is connected to the wiring 57c of the metal M₁₃ of the third layer and the like via a conductive via 64. As illustrated in FIG. 4B, the Cu diffusion barrier metal film 72 is provided between the second connecting wiring 58 and the second uppermost interlayer insulating film 56c. The second connecting wiring 58 and the Cu diffusion barrier metal film 72 face the surface S2. That is, the second connecting pad 58b faces the surface S2. Examples of the Cu diffusion barrier metal film include Ta, TaN, Ti, TiN, W, WN, Ru, TiZrN, and alloy films containing these. Furthermore, the second connecting pad 58b and a wiring of metal of the same layer as the second connecting pad 58b are referred to as a second wiring in order to be distinguished from other wirings.

The second semiconductor substrate 28 further includes a second antioxidant layer 76 provided in the second uppermost interlayer insulating film 56c. A surface of the second antioxidant layer 76 remote from the second uppermost interlayer insulating film 56c faces the surface S2.

The second antioxidant layer 76 includes a substance (insulating film) that is lower in hygroscopicity than the interlayer insulating film 56. The second antioxidant layer 76 includes an insulating film that is lower in hygroscopicity than the second uppermost interlayer insulating film 56c. Examples of the second antioxidant layer 76 include silicon nitride, alumina (Al₂O₃), and the like. In the first embodiment, the second antioxidant layer 76 includes silicon nitride. Silicon nitride is lower in hygroscopicity than SiO₂.

FIG. 3 illustrates the MOS transistors Tr₁₁ to Tr₁₄ as representative of the plurality of MOS transistors of the logic circuit 55.

In the multilayer wiring layer 59 of the second semiconductor substrate 28, the MOS transistors Tr₁₁ to Tr₁₄ and the wirings 57, and the wirings 57 of upper and lower layers adjacent to each other are connected via the conductive via 64.

[Configuration Example of Bonding Layer]

The first semiconductor substrate 26 and the second semiconductor substrate 28 are bonded together by atomic diffusion bonding. The first semiconductor substrate 26 and the second semiconductor substrate 28 are bonded together so as to cause the first uppermost interlayer insulating film 53c serving as the uppermost interlayer insulating film of the first semiconductor substrate 26 and the second uppermost interlayer insulating film 56c serving as the uppermost interlayer insulating film of the second semiconductor substrate 28 to face each other. The first semiconductor substrate 26 and the second semiconductor substrate 28 are bonded together so as to cause their respective uppermost interlayer insulating films to face each other.

Specifically, the atomic diffusion bonding refers to bonding by which a high melting point metal film is first formed on the surface S1 of the first semiconductor substrate 26 and the surface S2 of the second semiconductor substrate 28, and the high melting point metal films thus formed are bonded, thereby bonding the first semiconductor substrate 26 and the second semiconductor substrate 28 together. That is, such bonding corresponds to metal-metal bonding. Next, the first semiconductor substrate 26 and second semiconductor substrate 28 bonded together are subjected to heat treatment to convert a part of the high melting point metal films into an insulator. This prevents electrodes from being short-circuited, for example. Such a high melting point metal film forms a bonding layer 84 to be described below.

Furthermore, examples of a material of a high melting point metal used for atomic diffusion bonding include titanium (Ti), manganese (Mn), chromium (Cr), gold (Au), and the like. In the first embodiment, an example where titanium (Ti) is used as the high melting point metal will be described.

The bonding layer 84 is provided between the first semiconductor substrate 26 and the second semiconductor substrate 28 and is partially converted into an insulator as described above. As illustrated in FIG. 3, the bonding layer 84 includes an insulating layer 85, a light shielding layer 86, and a conducting layer 87.

First, the insulating layer 85 will be described. The insulating layer 85 is an insulator (oxide), that is, titanium dioxide (TiO₂), obtained as a result of oxidizing the above-described high melting point metal film by heat treatment to convert the high melting point metal film into an insulator. The insulating layer 85 corresponds to a part of the high melting point metal film that reacts with oxygen under the influence of humidity from the first uppermost interlayer insulating film 53c and the second uppermost interlayer insulating film 56c to become an oxide film. A plurality of conductors is insulated from each other by the insulating layer 85. The insulating layer 85 serves as an electrical insulator between the light shielding layer 86 and the conducting layer 87, between the plurality of conducting layers 87, and the like, for example.

Next, the conducting layer 87 will be described. The conducting layer 87 is a conductor, that is, titanium (Ti), corresponding to the high melting point metal film that is not oxidized and remains as it is. The conducting layer 87 corresponds to a part of the high melting point metal film that is not affected by humidity and remains as it without being oxidized because the part is separated from the first uppermost interlayer insulating film 53c by the first connecting pad 36b and is separated from the second uppermost interlayer insulating film 56c by the second connecting pad 58b. The conducting layer 87 serves as an electrical conductor between the first connecting pad 36b and the second connecting pad 58b.

Finally, the light shielding layer 86 will be described. The light shielding layer 86 is a conductor, that is, titanium (Ti), corresponding to the high melting point metal film that is not oxidized and remains as it is. The light shielding layer 86 corresponds to a part of the high melting point metal film that is not affected by humidity and remains as it is without being oxidized because the part is separated from the first uppermost interlayer insulating film 53c by the first antioxidant layer 71 and is separated from the second uppermost interlayer insulating film 56c by the second antioxidant layer 76.

FIG. 4A is a plan view schematically illustrating the solid-state imaging device 31 according to the first embodiment of the present technology. FIG. 4A schematically illustrates the light shielding layer 86, the first antioxidant layer 71, the second antioxidant layer 76, the first connecting pad 36b, the second connecting pad 58b, and the like for easy understanding. Therefore, the solid-state imaging device 31 illustrated in FIG. 4A has a portion that looks somewhat different from the solid-state imaging device 31 illustrated in FIG. 3.

The light shielding layer 86 serves as a shield between the first semiconductor substrate 26 and the second semiconductor substrate 28, and has a function of suppressing and blocking passage of noise from one semiconductor substrate of the first semiconductor substrate 26 or the second semiconductor substrate 28 toward the other semiconductor substrate. Note that examples of the noise include optical noise and electrical noise, and the light shielding layer 86 has a function of blocking any of such noises. For example, the light shielding layer 86 serves as a shield between the logic circuit 55 of the second semiconductor substrate 28 and the pixel region 34 of the first semiconductor substrate 26 and has a function of suppressing passage of noise such as electromagnetic waves from the logic circuit 55 of the second semiconductor substrate 28 toward the pixel region 34 of the first semiconductor substrate 26. In order to make such functions effective, as illustrated in FIG. 3, the light shielding layer 86 is provided between the second semiconductor substrate 28 and the first semiconductor substrate 26. Furthermore, the light shielding layer 86 is provided in alignment with at least one of a portion that needs to be protected from noise or a portion that is a main noise generation source in a case of being projected in the thickness direction, that is, in plan view. For example, as illustrated in FIG. 4A, in a case where the portion that needs to be protected from noise is the pixel region 34, the light shielding layer 86 is provided at a position that is in alignment with the pixel region 34 in a case of being projected in the thickness direction, that is, in plan view. Here, a longitudinal direction of the solid-state imaging device 31 in FIG. 4A is parallel to an X direction, and a lateral direction is parallel to a Y direction. Moreover, the thickness direction of the solid-state imaging device 31 is parallel to a Z direction. The X direction, the Y direction, and the Z direction are orthogonal to each other. The light shielding layer 86 is larger in area than the pixel region 34, and an outline 86a of the light shielding layer 86 is provided outside an outline 34a of the pixel region 34. Being provided outside means that the outline 86a of the light shielding layer 86 is closer to an outline 31a of the solid-state imaging device 31 than the outline 34a of the pixel region 34. As described above, the light shielding layer 86 is provided all over the pixel region 34.

Furthermore, in order to provide the light shielding layer 86 as described above at the position illustrated in FIG. 4A, the first antioxidant layer 71 and the second antioxidant layer 76 are also provided at a position that is in alignment with the pixel region 34 in a case of being projected in the thickness direction, that is, in plan view. The first antioxidant layer 71 is larger in area than the pixel region 34, and an outline 71a of the first antioxidant layer 71 is provided outside the outline 34a of the pixel region 34. The second antioxidant layer 76 is larger in area than the pixel region 34, and an outline 76a of the second antioxidant layer 76 is provided outside the outline 34a of the pixel region 34.

Then, as illustrated in FIGS. 3 and 4A, the light shielding layer 86 is provided at a position that is in perfect alignment with the first antioxidant layer 71 and the second antioxidant layer 76 in plan view and is perfectly aligned with the first antioxidant layer 71 and the second antioxidant layer 76 in the thickness direction. Specifically, the light shielding layer 86 is provided all over the surface of the first antioxidant layer 71 facing the surface S1, and a surface of the light shielding layer 86 adjacent to the first semiconductor substrate 26 is in contact with the surface of the first antioxidant layer 71 facing the surface S1. Furthermore, the light shielding layer 86 is provided all over the surface of the second antioxidant layer 76 facing the surface S2, and a surface of the light shielding layer 86 adjacent to the second semiconductor substrate 28 is in contact with the surface of the second antioxidant layer 76 facing the surface S2. As described above, the light shielding layer 86 is provided between the first antioxidant layer 71 and the second antioxidant layer 76. Furthermore, as illustrated in FIG. 4A, the light shielding layer 86, the first antioxidant layer 71, and the second antioxidant layer 76 each have a square shape with a side length Lc, and are equal in area to each other.

FIG. 4B is a cross-sectional view illustrating a cross-sectional structure taken along the line A-A in FIG. 4A. The insulating layer 85 includes a first insulating layer (first insulating film) 78 adjacent to the first semiconductor substrate 26 and a second insulating layer (third insulating film) 79 adjacent to the second semiconductor substrate 28. The light shielding layer 86 includes a first light shielding layer (second metal film) 80 adjacent to the first semiconductor substrate 26 and a second light shielding layer (fourth metal film) 81 adjacent to the second semiconductor substrate 28. The conducting layer 87 includes a first conducting layer (first metal film) 82 adjacent to the first semiconductor substrate 26 and a second conducting layer (third metal film) 83 adjacent to the second semiconductor substrate 28. The first antioxidant layer 71 is an antioxidant layer provided in the first semiconductor substrate 26, and the second antioxidant layer 76 is an antioxidant layer provided in the second semiconductor substrate 28. That is, the antioxidant layer is provided in both the first semiconductor substrate 26 and the second semiconductor substrate 28. The first light shielding layer, the second light shielding layer, the first conducting layer, and the second conducting layer are all metal films. Furthermore, the first uppermost interlayer insulating film 53c is in contact with the first wiring, the first insulating layer 78, and the first antioxidant layer 71.

The first antioxidant layer (second insulating film) 71 separates the light shielding layer 86 from the first uppermost interlayer insulating film 53c. Specifically, the first antioxidant layer 71 separates the first light shielding layer 80 from the first uppermost interlayer insulating film 53c.

The first light shielding layer 80 is provided at a position that is in perfect alignment with the first antioxidant layer 71 in plan view and is perfectly aligned with the first antioxidant layer 71 in the thickness direction. Specifically, the first light shielding layer 80 is provided all over the surface of the first antioxidant layer 71 facing the surface S1, and a surface of the first light shielding layer 80 adjacent to the first semiconductor substrate 26 is in contact with the surface of the first antioxidant layer 71 facing the surface S1.

The second antioxidant layer (fourth insulating film) 76 separates the light shielding layer 86 from the second uppermost interlayer insulating film 56c. Specifically, the second antioxidant layer 76 separates the second light shielding layer 81 from the second uppermost interlayer insulating film 56c.

The second light shielding layer 81 is provided at a position that is in perfect alignment with the second antioxidant layer 76 in plan view and is perfectly aligned with the second antioxidant layer 76 in the thickness direction. Specifically, the second light shielding layer 81 is provided all over the surface of the second antioxidant layer 76 facing the surface S2, and a surface of the second light shielding layer 81 adjacent to the second antioxidant layer 76 is in contact with the surface of the second antioxidant layer 76 facing the surface S2.

Furthermore, a surface of the first light shielding layer 80 adjacent to the second semiconductor substrate 28 and a surface of the second light shielding layer 81 adjacent to the first semiconductor substrate 26 are bonded together by atomic diffusion.

The first connecting pad 36b separates the conducting layer 87 from the first uppermost interlayer insulating film 53c. Specifically, the first connecting pad 36b separates the first conducting layer 82 from the first uppermost interlayer insulating film 53c. The first conducting layer 82 is provided all over a surface of the first connecting pad 36b facing the surface S1, and a surface of the first conducting layer 82 adjacent to the first semiconductor substrate 26 is in contact with the surface of the first connecting pad 36b facing the surface S1. Furthermore, the first conducting layer 82 is perfectly aligned with the first connecting pad 36b in the thickness direction.

The second connecting pad 58b separates the conducting layer 87 from the second uppermost interlayer insulating film 56c. Specifically, the second connecting pad 58b separates the second conducting layer 83 from the second uppermost interlayer insulating film 56c. The second conducting layer 83 is provided all over a surface of the second connecting pad 58b facing the surface S2, and a surface of the second conducting layer 83 adjacent to the second semiconductor substrate 28 is in contact with the surface of the second connecting pad 58b facing the surface S2. Furthermore, the second conducting layer 83 is perfectly aligned with the second connecting pad 58b in the thickness direction.

Furthermore, a surface of the first conducting layer 82 adjacent to the second semiconductor substrate 28 and a surface of the second conducting layer 83 adjacent to the first semiconductor substrate 26 are bonded together by atomic diffusion.

The first insulating layer 78 is provided all over a surface of the first uppermost interlayer insulating film 53c facing the surface S1, and a surface of the first insulating layer 78 adjacent to the first semiconductor substrate 26 is in contact with the surface of the first uppermost interlayer insulating film 53c facing the surface S1.

The second insulating layer 79 is provided all over a surface of the second uppermost interlayer insulating film 56c facing the surface S2, and a surface of the second insulating layer 79 adjacent to the second semiconductor substrate 28 is in contact with the surface of the second uppermost interlayer insulating film 56c facing the surface S2.

Furthermore, a surface of the first insulating layer 78 adjacent to the second semiconductor substrate 28 and a surface of the second insulating layer 79 adjacent to the first semiconductor substrate 26 are bonded together by atomic diffusion before being oxidized.

<Example of Method for Manufacturing Solid-State Imaging Device>

Hereinafter, an example of a method for manufacturing the solid-state imaging device 31 according to the first embodiment will be described with reference to the drawings. First, an example of a method for manufacturing the first semiconductor substrate 26 side including the pixel region will be described.

[Example of Method for Manufacturing First Semiconductor Substrate Side]

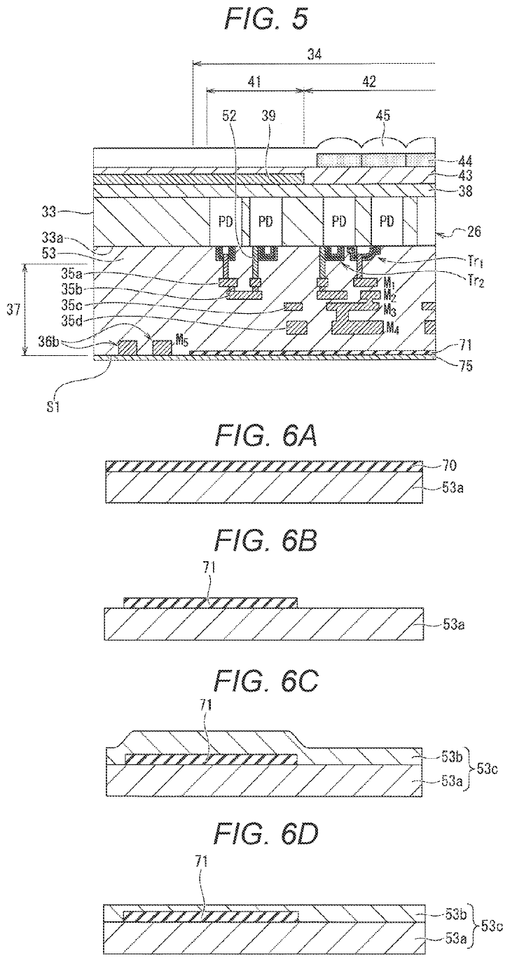

FIG. 5 is a configuration diagram schematically illustrating a main part of the first semiconductor substrate 26 side according to the first embodiment of the present technology.

In order to obtain such a first semiconductor substrate 26 side, the photodiode PD to be a photoelectric conversion unit of each pixel is formed in a region to be an individual semiconductor chip part of the first semiconductor wafer including silicon, for example. The photodiode PD is formed in the effective pixel region 42 and the optical black region 41 constituting the pixel region 34.

Moreover, a plurality of pixel transistors constituting each pixel is formed on the surface 33a of the first semiconductor layer 33. The pixel transistors may include, for example, a transfer transistor, a reset transistor, an amplification transistor, and a selection transistor. Here, as described above, the pixel transistors Tr₁ and Tr₂ are illustrated as representative pixel transistors. Although not illustrated, the pixel transistors Tr₁ and Tr₂ each include a pair of source-drain regions and a gate electrode formed via a gate insulating film.

On the surface 33a of the first semiconductor layer 33, the plurality of (in this example, four) layers of the wirings 35 [35a, 35b, 35c, 35d] of the metals M₁ to M₄ is formed together with the conductive via 52 via the interlayer insulating film 53. The wirings 35 may be formed by dual damascene. That is, a connecting hole and a wiring groove are simultaneously formed, by via first, in the interlayer insulating film 53, a Cu diffusion barrier metal film for preventing Cu diffusion is formed, and then a Cu material layer is embedded by plating. Next, an unnecessary Cu material layer is removed by chemical mechanical polishing (CMP) to form a planarized Cu wiring integrated with a conductive via. Thereafter, a Cu diffusion barrier insulating film (not illustrated) is formed. Examples of the Cu barrier insulating film may include an insulating film such as silicon nitride, SiC, siCN, or SiON. This process is repeated to form the four layers of the wirings 35a to 35d of the metals M₁ to M₄.

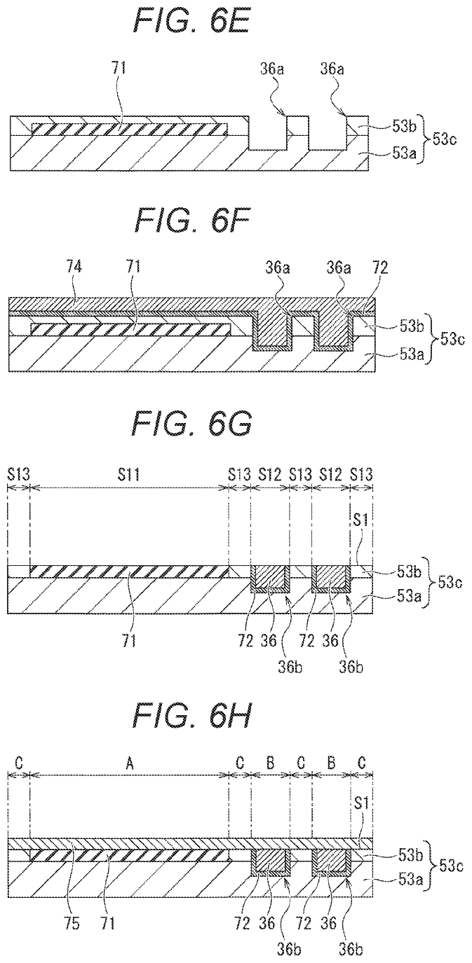

Thereafter, as illustrated in FIG. 5, the interlayer insulating film 53 is formed to cover the metal M₄. Next, the first antioxidant layer 71, the first connecting pad 36b, and the conductive via 52 (not illustrated) connecting the first connecting pad 36b and the wirings 35 are formed, and a first high melting point metal film 75 is formed. A method for forming the first antioxidant layer 71, the first connecting pad 36b, and the first high melting point metal film 75 will be described in detail with reference to FIGS. 6A to 6H. Here, the layers before the metal M₄ are not illustrated.

First, as illustrated in FIG. 6A, an interlayer insulating film 53a is formed to cover the metal M₄. An antioxidant film 70 is further formed to cover the interlayer insulating film 53a. Next, as illustrated in FIG. 6B, an unnecessary portion of the antioxidant film 70 is removed by lithography and etching to form the first antioxidant layer 71. As the etching, dry etching is used. Removing the unnecessary portion allows the first antioxidant layer 71 to be formed in a region where the first light shielding layer 80 is to be disposed.

Then, as illustrated in FIG. 6C, an interlayer insulating film 53b is formed to cover the first antioxidant layer 71. Here, the first uppermost interlayer insulating film 53c includes the interlayer insulating film 53a and the interlayer insulating film 53b. Next, as illustrated in FIG. 6D, a surface of the first uppermost interlayer insulating film 53c (interlayer insulating film 53b) is planarized by CMP. At this time, the first antioxidant layer 71 is not exposed to the surface of the interlayer insulating film 53b.

Next, as illustrated in FIG. 6E, the wiring groove 36a is formed in the first uppermost interlayer insulating film 53c by lithography and etching. Then, as illustrated in FIG. 6F, the Cu diffusion barrier metal film 72 is formed to cover the first uppermost interlayer insulating film 53c in which the wiring groove 36a is formed. Thereafter, a Cu material layer 74 is embedded, by plating, in the wiring groove 36a in which the Cu diffusion barrier metal film 72 is formed.

Next, unnecessary portions of the Cu material layer 74, the Cu diffusion barrier metal film 72, and the first uppermost interlayer insulating film 53c are removed by CMP. The unnecessary portions are polished until the surface is planarized and the first antioxidant layer 71 is exposed. Note that the condition of CMP is set to make the first antioxidant layer 71 less prone to dishing, for example. As a result, as illustrated in FIG. 6G, the planarized surface S1 is obtained, and the first connecting pad 36b is formed. Then, the surface S1 includes a surface S11 (third region) of the first antioxidant layer 71 facing the surface S1, a surface S12 (second region) of the first connecting pad 36b and the wiring of metal of the same layer as the first connecting pad 36b facing the surface S1, and a surface S13 (first region) of the first uppermost interlayer insulating film 53c facing the surface S1.

Next, as illustrated in FIG. 6H, the first high melting point metal film 75 is formed to cover the surface S1 of the first semiconductor substrate 26 obtained as described above. A high melting point metal is subjected to sputtering in vacuum to form the first high melting point metal film 75. Here, of the first high melting point metal film 75, a portion that is in contact with the surface S11 is referred to as a first portion A, a portion that is in contact with the surface S12 is referred to as a second portion B, and a portion that is in contact with the surface S13 is referred to as a third portion C. The above is the description of the example of the method for manufacturing the first semiconductor substrate side.

[Example of Method for Manufacturing Second Semiconductor Substrate Side]

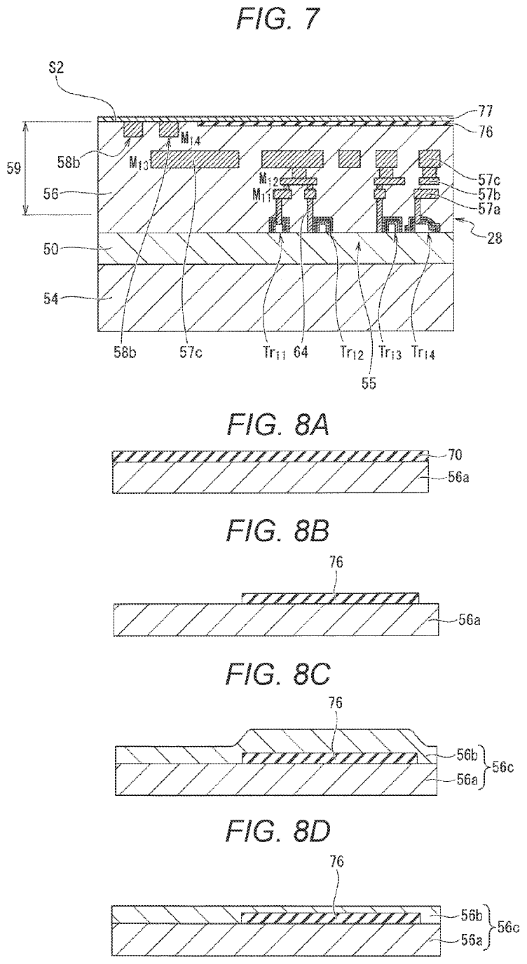

Next, an example of a method for manufacturing the second semiconductor substrate 28 side including the logic circuit will be described. FIG. 7 is a configuration diagram schematically illustrating a main part of the second semiconductor substrate 28 side according to the first embodiment of the present technology. In order to obtain such a second semiconductor substrate 28 side, the plurality of MOS transistors Tr₁₁ to Tr₁₄ constituting the logic circuit 55 is formed in a region to be an individual semiconductor chip part of the second semiconductor wafer including silicon, for example. Here, as described above, the MOS transistors Tr₁₁ to Tr₁₄ are illustrated as representative MOS transistors.

Over the surface of the second semiconductor layer 54, the plurality of (in this example, three) layers of the wirings 57 [57a, 57b, 57c] of the metals M₁₁ to M₁₃ is formed together with the conductive via 64 via the interlayer insulating film 56. The wirings 57 may be formed by dual damascene. That is, a connecting hole and a wiring groove are simultaneously formed, by via first, in an interlayer insulating film, a Cu diffusion barrier metal film for preventing Cu diffusion and a Cu seed film are formed, and then a Cu material layer is embedded by plating. Next, an unnecessary Cu material layer is removed by chemical mechanical polishing (CMP) to form a planarized Cu wiring integrated with a conductive via. Thereafter, a Cu diffusion barrier insulating film (not illustrated) is formed. Examples of the Cu barrier insulating film may include an insulating film such as silicon nitride, SiC, siCN, or SiON. This process is repeated to form the three layers of the wirings 57a to 57c of the metals M₁₁ to M₁₃.

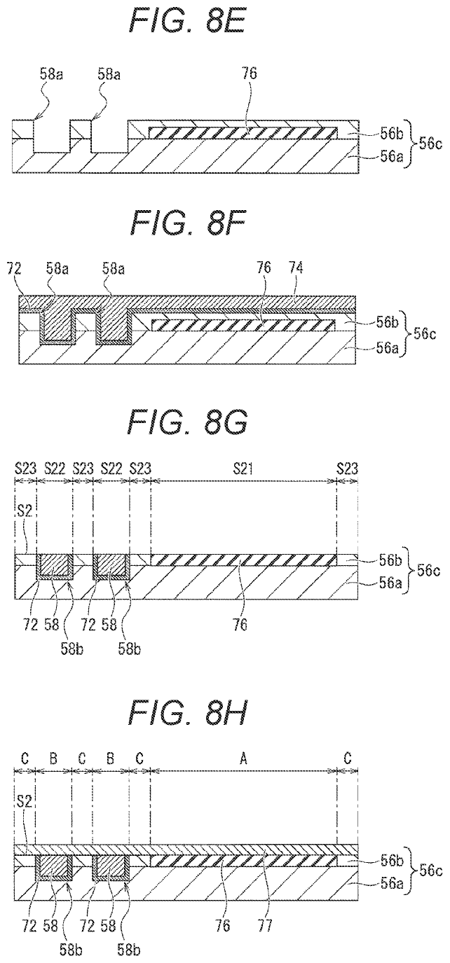

Thereafter, as illustrated in FIG. 7, the interlayer insulating film 56 is formed to cover the metal M₁₃. Next, the second antioxidant layer 76, the second connecting pad 58b, and the conductive via 64 (not illustrated) connecting the second connecting pad 58b and the wirings 57 are formed. Then, a second high melting point metal film 77 is formed. A method for forming the second antioxidant layer 76, the second connecting pad 58b, and the second high melting point metal film 77 will be described in detail with reference to FIGS. 8A to 8H. Here, the layers before the metal M₁₃ are not illustrated.

First, as illustrated in FIG. 8A, an interlayer insulating film 56a is formed to cover the metal M₁₃. An antioxidant film 70 is further form to cover the interlayer insulating film 56a. Next, as illustrated in FIG. 8B, an unnecessary portion of the antioxidant film 70 is removed by lithography and etching to form the second antioxidant layer 76. As the etching, dry etching is used. Removing the unnecessary portion allows the second antioxidant layer 76 to be formed in a region where the second light shielding layer 81 is to be disposed.

Then, as illustrated in FIG. 8C, an interlayer insulating film 56b is formed to cover the second antioxidant layer 76. Here, the second uppermost interlayer insulating film 56c includes the interlayer insulating film 56a and the interlayer insulating film 56b. Next, as illustrated in FIG. 8D, a surface of the second uppermost interlayer insulating film 56c (interlayer insulating film 56b) is planarized by CMP. At this time, the second antioxidant layer 76 is not exposed to the surface of the interlayer insulating film 56b.

Next, as illustrated in FIG. 8E, the wiring groove 58a is formed in the second uppermost interlayer insulating film 56c by lithography and etching. Then, as illustrated in FIG. 8F, the Cu diffusion barrier metal film 72 is formed to cover the second uppermost interlayer insulating film 56c in which the wiring groove 58a is formed. Thereafter, a Cu material layer 74 is embedded, by plating, in the wiring groove 58a in which the Cu diffusion barrier metal film 72 is formed.

Next, unnecessary portions of the Cu material layer 74, the Cu diffusion barrier metal film 72, and the second uppermost interlayer insulating film 56c are removed by CMP. The unnecessary portions are polished until the surface is planarized and the second antioxidant layer 76 is exposed. Note that the condition of CMP is set to make the second antioxidant layer 76 less prone to dishing, for example. As a result, as illustrated in FIG. 8G, the planarized surface S2 is obtained, and the second connecting pad 58b is formed. Then, the surface S2 includes a surface S21 (sixth region) of the second antioxidant layer 76 facing the surface S2, a surface S22 (fifth region) of the second connecting pad 58b and the wiring of metal of the same layer as the second connecting pad 58b facing the surface S2, and a surface S23 (fourth region) of the second uppermost interlayer insulating film 56c facing the surface S2.

Next, as illustrated in FIG. 8H, the second high melting point metal film 77 is formed to cover the surface S2 of the second semiconductor substrate 28 obtained as described above. A high melting point metal is subjected to sputtering in vacuum to form the second high melting point metal film 77. Here, of the second high melting point metal film 77, a portion that is in contact with the surface S21 is referred to as a first portion A, a portion that is in contact with the surface S22 is referred to as a second portion B, and a portion that is in contact with the surface S23 is referred to as a third portion C. The above is the description of the example of the method for manufacturing the second semiconductor substrate 28 side. Note that, for example, the second high melting point metal film 77 may include the same material as the first high melting point metal film 75, and may be identical in thickness to the first high melting point metal film 75.

[Formation Example of Bonding Layer]

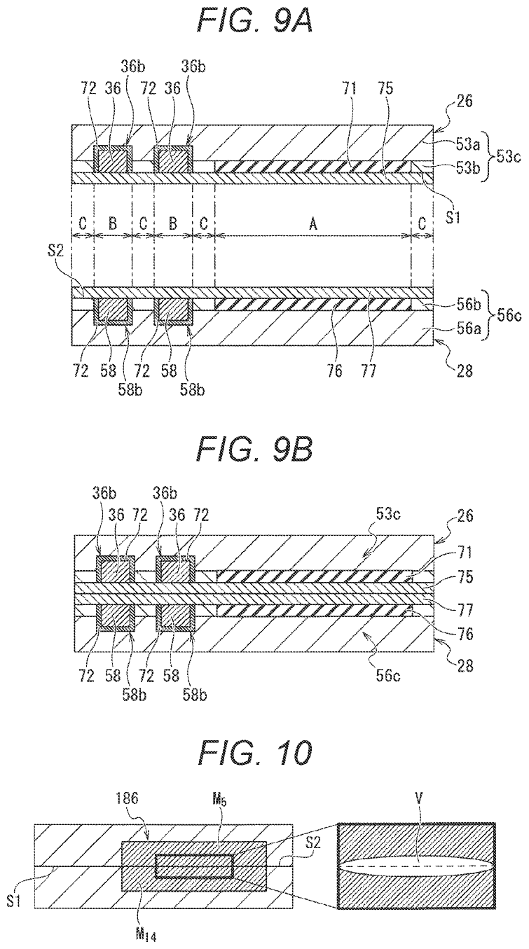

Hereinafter, an example of forming the bonding layer 84 by bonding the first semiconductor substrate 26 side and the second semiconductor substrate 28 side together will be described in detail with reference to FIGS. 9A to 9B. First, as illustrated in FIG. 9A, the first semiconductor substrate 26 side and the second semiconductor substrate 28 side are prepared so as to cause their respective high melting point metal films to face each other. At this time, the first semiconductor substrate 26 side and the second semiconductor substrate 28 side are aligned so as to cause the first portion A of the first semiconductor substrate 26 side and the first portion A of the second semiconductor substrate 28 side to align with each other, cause the second portion B of the first semiconductor substrate 26 side and the second portion B of the second semiconductor substrate 28 to align with each other, and cause the third portion C of the first semiconductor substrate 26 side and the third portion C of the second semiconductor substrate 28 side to align with each other in the thickness direction.

Next, as illustrated in FIG. 9B, the first semiconductor substrate 26 side and the second semiconductor substrate 28 side are placed on top of each other so as to bring their respective high melting point metal films into contact with each other. As a result, their respective high melting point metal films are bonded together to form a single body. Then, the first semiconductor substrate 26 and second semiconductor substrate 28 bonded together are subjected to heat treatment. This heat treatment is performed to convert their respective third portions C of the first high melting point metal film 75 and the third portion C of the second high melting point metal film 77 into an insulating film. This heat treatment is performed, for example, in an oxygen gas atmosphere or a water vapor atmosphere.

The third portion C of the first high melting point metal film 75 is a portion that is in direct contact with the first uppermost interlayer insulating film 53c. Under the heat treatment, the third portion C of the first high melting point metal film 75 reacts with oxygen under the influence of humidity from the first uppermost interlayer insulating film 53c to become an oxide film. In the first embodiment, since titanium (Ti) is used as the high melting point metal, Ti in the first portion reacts with oxygen to become TiO₂ which is an insulating film.

Likewise, the third portion C of the second high melting point metal film 77 is a portion that is in direct contact with the second uppermost interlayer insulating film 56c. Under the heat treatment, the third portion C of the second high melting point metal film 77 reacts with oxygen under the influence of humidity from the second uppermost interlayer insulating film 56c to become an oxide film. In the first embodiment, since titanium (Ti) is used as the high melting point metal, Ti in the first portion reacts with oxygen to become titanium dioxide (TiO₂) which is an insulating film.

As described above, the third portion C of the first high melting point metal film 75 and the third portion C of the second high melting point metal film 77 are oxidized to form the first insulating layer 78 and the second insulating layer 79, respectively.

The first portion A of the first high melting point metal film 75 is in contact with the first antioxidant layer 71 that is lower in hygroscopicity than the first uppermost interlayer insulating film 53c. That is, the first uppermost interlayer insulating film 53c and the first portion A of the first high melting point metal film 75 are separated from each other by the first antioxidant layer 71 that is lower in hygroscopicity. Such a structure prevents the first portion A of the first high melting point metal film 75 from being directly affected by humidity from the first uppermost interlayer insulating film 53c. As a result, the first portion A of the first high melting point metal film 75 is not oxidized and remains as it is. In the first embodiment, since titanium (Ti) is used as the high melting point metal, the titanium (Ti) is not oxidized and remains as it is.

Likewise, the first portion A of the second high melting point metal film 77 is in contact with the second antioxidant layer 76 that is lower in hygroscopicity than the second uppermost interlayer insulating film 56c. That is, the second uppermost interlayer insulating film 56c and the first portion A of the second high melting point metal film 77 are separated from each other by the second antioxidant layer 76 that is lower in hygroscopicity. Such a structure prevents the first portion A of the second high melting point metal film 77 from being directly affected by humidity from the second uppermost interlayer insulating film 56c. As a result, the first portion A of the second high melting point metal film 77 is not oxidized and remains as it is. In the first embodiment, since titanium (Ti) is used as the high melting point metal, the titanium (Ti) is not oxidized and remains as it is.

As described above, the first portion A of the first high melting point metal film 75 and the first portion A of the second high melting point metal film 77 are not oxidized and remain as they are even after the heat treatment, thereby forming the first light shielding layer 80 and the second light shielding layer 81.

The second portion B of the first high melting point metal film 75 is in contact with the first connecting pad 36b. That is, the first uppermost interlayer insulating film 53c and the second portion B of the first high melting point metal film 75 are separated from each other by the first connecting pad 36b. Such a structure prevents the second portion B of the first high melting point metal film 75 from being directly affected by humidity from the first uppermost interlayer insulating film 53c. As a result, the second portion B of the first high melting point metal film 75 is not oxidized and remains as it is. In the first embodiment, since titanium (Ti) is used as the high melting point metal, the titanium (Ti) is not oxidized and remains as it is.

Likewise, the second portion B of the second high melting point metal film 77 is in contact with the second connecting pad 58b. That is, the second uppermost interlayer insulating film 56c and the second portion B of the second high melting point metal film 77 are separated from each other by the second connecting pad 58b. Such a structure prevents the second portion B of the second high melting point metal film 77 from being directly affected by humidity from the second uppermost interlayer insulating film 56c. As a result, the second portion B of the second high melting point metal film 77 is not oxidized and remains as it is. The above is the description of the bonding between the first semiconductor substrate 26 and the second semiconductor substrate 28 and the heat treatment performed on the first semiconductor substrate 26 and the second semiconductor substrate 28 bonded together. In the first embodiment, since titanium (Ti) is used as the high melting point metal, the titanium (Ti) is not oxidized and remains as it is.

As described above, the second portion B of the first high melting point metal film 75 and the second portion B of the second high melting point metal film 77 are not oxidized and remain as they are even after the heat treatment, thereby forming the first conducting layer 82 and the second conducting layer 83. The second connecting pad 58b is electrically connected to the first connecting pad 36b via the conducting layer 87.

As described above, the first semiconductor substrate 26 and the second semiconductor substrate 28 are bonded together. Then, as illustrated in FIG. 4B, the bonding layer 84 including the insulating layer 85, the light shielding layer 86, and the conducting layer 87 is formed.

[Thinning, Lens Formation, and Chipping]

Next, the first semiconductor wafer and the second semiconductor wafer bonded together as described above are thinned by being ground and polished by CMP or the like from the back surface so that a required film thickness of the photodiode PD remains. Next, on the thinned surface, the light-receiving-side light-shielding film 39 is formed to cover a region on the photodiode PD corresponding to the optical black region with the light-receiving-side insulating film 38 interposed between the light-receiving-side light shielding film 39 and the photodiode PD. Furthermore, the color filter 44 and the on-semiconductor chip lens 45 are formed on the photodiode PD corresponding to the effective pixel region with the planarization film 43 interposed between the color filter 44 and the on-semiconductor chip lens 45, and the photodiode PD.

Next, the first semiconductor wafer and second semiconductor wafer bonded together are separated into semiconductor chips, thereby obtaining the intended solid-state imaging device 31 illustrated in FIG. 3. The above is an example of the method for manufacturing the solid-state imaging device 31.

<Effect>

Here, first, a comparative example of the light shielding layer will be described. As illustrated in FIG. 10, in a case where a light shielding layer 186 having a large area as a countermeasure against noise includes the metal M₅ of the fifth layer facing the surface S1 of the first semiconductor substrate 26 and the metal M₁₄ of the fourth layer facing the surface S2 of the second semiconductor substrate 28, there is a possibility that the metal M₅ and the metal M₁₄ suffer dishing due to CMP before bonding, and a gap V is generated between the metal M₅ and the metal M₁₄. In this case, the bonding strength between the first semiconductor substrate 26 and the second semiconductor substrate 28 decreases.

Furthermore, in order to improve the bonding strength, a hole may be made in a part of the metal M₅ and the metal M₁₄ to provide a bonding portion between the insulating films. This, however, forms a gap through which noise can pass in the light shielding layer 186.

Furthermore, in a case where a metal and an insulating film, for example, different materials such as CU and SiO₂, are bonded together, the bonding strength is lower than in a case where the same type of materials, for example, metals or insulating films, are bonded together. It is therefore more effective that either the bonding between metals or the bonding between insulating films be applied in terms of strength.

In the solid-state imaging device 31 according to the first embodiment, the first high melting point metal film 75 and the second high melting point metal film 77 are bonded together by atomic diffusion to form the light shielding layer 86 and bond the first semiconductor substrate 26 and the second semiconductor substrate 28 together. This bonding corresponds to the bonding between metals and thus can obtain higher bonding strength than the bonding between different materials such as a metal and an insulating film.

Furthermore, in the solid-state imaging device 31 according to the first embodiment, providing the first antioxidant layer 71 and the second antioxidant layer 76 allows the high melting point metal to remain as the light shielding layer 86, so that it is possible to provide the light shielding layer 86 having a large area under the pixel region 34. It is therefore possible to suppress passage of noise such as electromagnetic waves between the first semiconductor substrate 26 side and the second semiconductor substrate 28 side while improving the bonding strength between the first semiconductor substrate 26 side and the second semiconductor substrate 28 side.

Note that, in FIG. 4A, the potential of the light shielding layer 86 is not fixed, but may be fixed. The potential may be fixed at, for example, a ground potential.

<Modification 1 of First Embodiment>

<Configuration Example of Solid-State Imaging Device>

A modification 1 of the first embodiment of the present technology will be described below. The modification 1 of the first embodiment is different from the above-described first embodiment in that a bonding layer 84A is provided instead of the bonding layer 84, and the other configuration of the solid-state imaging device 31 is basically similar to the configuration of the solid-state imaging device 31 of the first embodiment described above.

[Configuration Example of Bonding Layer]

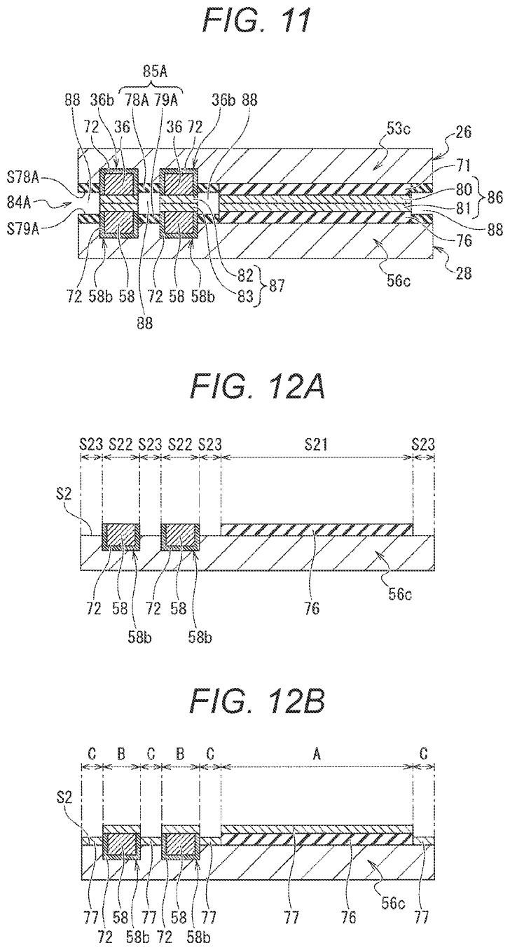

As illustrated in FIG. 11, the bonding layer 84A includes an insulating layer 85A, a light shielding layer 86, a conducting layer 87, and a gap 88. The insulating layer 85A includes a first insulating layer 78A adjacent to the first semiconductor substrate 26 and a second insulating layer 79A adjacent to the second semiconductor substrate 28. The first insulating layer 78A and the second insulating layer 79A are provided apart from each other in the thickness direction.

A surface S78A of the first insulating layer 78A remote from the first uppermost interlayer insulating film 53c is provided adjacent to the first uppermost interlayer insulating film 53c relative to the surface S12. That is, the surface S78A is provided adjacent to the first uppermost interlayer insulating film 53c relative to a boundary between the first connecting pad 36b and the first conducting layer 82. The first connecting pad 36b therefore protrudes from the surface S78A.

Furthermore, a surface S79A of the second insulating layer 79A remote from the second uppermost interlayer insulating film 56c is provided adjacent to the second uppermost interlayer insulating film 56c relative to the surface S22. That is, the surface S79A is provided adjacent to the second uppermost interlayer insulating film 56c relative to a boundary between the second connecting pad 58b and the second conducting layer 83. The second connecting pad 58b therefore protrudes from the surface S79A.

The surface S78A and the surface S79A are apart from each other in the thickness direction. Furthermore, a distance between the surface S78A and the surface S79A in the thickness direction is larger than a thickness of the conducting layer 87.

The gap 88 is provided between the first insulating layer 78A and the second insulating layer 79A in the thickness direction. The gap 88 is in contact with each of the first connecting pad 36b, the conducting layer 87, and the second connecting pad 58b electrically connected to the first connecting pad 36b via the conducting layer 87. Furthermore, the gap 88 is provided adjacent to a boundary between the first connecting pad 36b and the first conducting layer 82, a boundary between the first conducting layer 82 and the second conducting layer 83, and a boundary between the second connecting pad 58b and the second conducting layer 83 in a direction orthogonal to the thickness direction.

The insulating layer 85A and the gap 88 each serves as an electrical insulator between the light shielding layer 86 and the conducting layer 87, between the plurality of conducting layers 87, between the light shielding layer 86 and the first connecting pad 36b, between the light shielding layer 86 and the second connecting pad 58b, and the like, for example.

<Example of Method for Manufacturing Solid-State Imaging Device>

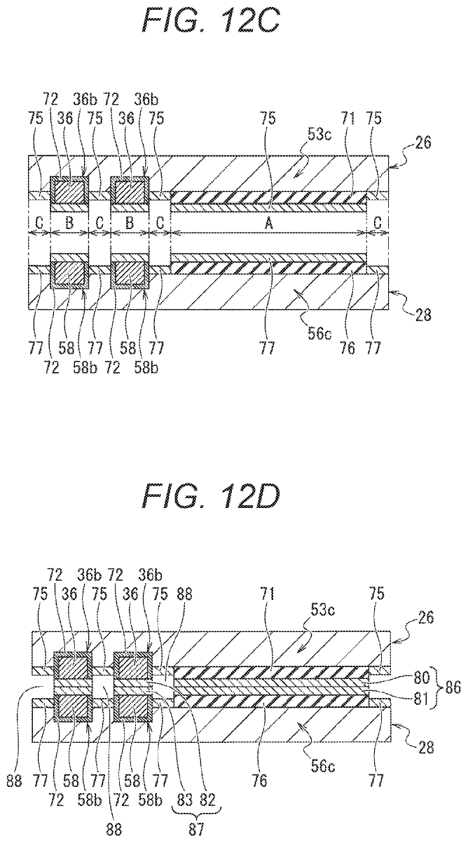

Hereinafter, a method for manufacturing the solid-state imaging device 31 will be described with reference to FIGS. 12A to 12D. Here, the first semiconductor substrate 26 side and the second semiconductor substrate 28 side are prepared, but since the configuration related to the bonding portion is the same between the first semiconductor substrate 26 side and the second semiconductor substrate 28 side, a method for manufacturing the second semiconductor substrate 28 side will be described below as a representative method with reference to the drawings. Note that no detailed description will be given of the same process as in the first embodiment.

First, as illustrated in FIG. 8F of the first embodiment, the second antioxidant layer 76, the wiring groove 58a, the Cu diffusion barrier metal film 72, and the Cu material layer 74 are sequentially formed. Next, as illustrated in FIG. 12A, unnecessary portions of the Cu diffusion barrier metal film 72, the Cu material layer 74, and the second uppermost interlayer insulating film 56c are removed by CMP. At this time, only the second uppermost interlayer insulating film 56c is subjected to dishing by making effective use of slurry selectivity. As a result, the surface S2 of the second semiconductor substrate 28 is obtained. The surface S2 has irregularities. Then, the surface S2 includes a surface S21 of the second antioxidant layer 76 facing the surface S2, a surface S22 of the second connecting pad 58b facing the surface S2, and a surface S23 of the second uppermost interlayer insulating film 56c facing the surface S2. The surface S21, the surface S22, and the surface S23 are surfaces perpendicular to the thickness direction. Next, as illustrated in FIG. 12B, the second high melting point metal film 77 is formed to cover the surface S2 of the second semiconductor substrate 28. Here, of the second high melting point metal film 77, a portion that is in contact with the surface S21 is referred to as a first portion A, a portion that is in contact with the surface S22 is referred to as a second portion B, and a portion that is in contact with the surface S23 is referred to as a third portion C. As described above, the second semiconductor substrate 28 side is obtained. Then, the first semiconductor substrate 26 side in which only the first uppermost interlayer insulating film 53c is subjected to dishing is obtained in the similar manner.

Next, as illustrated in FIG. 12C, the first semiconductor substrate 26 side and the second semiconductor substrate 28 side are prepared so as to cause their respective high melting point metal films to face each other. At this time, the first semiconductor substrate 26 side and the second semiconductor substrate 28 side are aligned so as to cause the first portion A of the first semiconductor substrate 26 side and the first portion A of the second semiconductor substrate 28 side to align with each other, cause the second portion B of the first semiconductor substrate 26 side and the second portion B of the second semiconductor substrate 28 to align with each other, and cause the third portion C of the first semiconductor substrate 26 side and the third portion C of the second semiconductor substrate 28 side to align with each other in the thickness direction.

Next, as illustrated in FIG. 12D, the first semiconductor substrate 26 side and the second semiconductor substrate 28 side are placed on top of each other so as to bring their respective high melting point metal films into contact with each other. As a result, their respective high melting point metal films are bonded together to form a single body. The first portion A of the first semiconductor substrate 26 side and the first portion A of the second semiconductor substrate 28 side come into contact with each other to form the light shielding layer 86. The second portion B of the first semiconductor substrate 26 side and the second portion B of the second semiconductor substrate 28 side come into contact with each other to form the conducting layer 87. On the other hand, the third portion C of the first semiconductor substrate 26 side and the third portion C of the second semiconductor substrate 28 side are not in contact with each other because the first uppermost interlayer insulating film 53c and the second uppermost interlayer insulating film 56c are subjected to dishing, and therefore are not bonded. Then, the gap 88 is formed between the third portion C of the first semiconductor substrate 26 side and the third portion C of the second semiconductor substrate 28 side.

Next, the first semiconductor substrate 26 and the second semiconductor substrate 28 in FIG. 12D are subjected to heat treatment. Under the heat treatment, the third portion C of the first semiconductor substrate 26 side reacts with oxygen to become titanium dioxide (TiO₂), thereby forming the second insulating layer 79A. Then, the third portion C of the second semiconductor substrate 28 side reacts with oxygen to become titanium dioxide (TiO₂), thereby forming the first insulating layer 78A. As a result, the insulating layer 85A is formed.

As described above, the bonding layer 84A including the insulating layer 85A, the light shielding layer 86, the conducting layer 87, and the gap 88 illustrated in FIG. 11 is formed. The above is an example of the method for manufacturing the solid-state imaging device 31.

<Effect>

The solid-state imaging device 31 according to the modification 1 of the first embodiment produces effects similar to the effects produced by the solid-state imaging device 31 according to the first embodiment described above.

Furthermore, since the solid-state imaging device 31 according to the modification 1 of the first embodiment includes the gap 88, it is possible to improve electromigration resistance of the first connecting pad 36b and the second connecting pad 58b.

<Modification 2 of First Embodiment>

<Configuration Example of Solid-State Imaging Device>

A modification 2 of the first embodiment of the present technology will be described below. The modification 2 of the first embodiment is different from the above-described first embodiment in that a bonding layer 84B is provided instead of the bonding layer 84, and the other configuration of the solid-state imaging device 31 is basically similar to the configuration of the solid-state imaging device 31 of the first embodiment described above.

[Configuration Example of Bonding Layer]

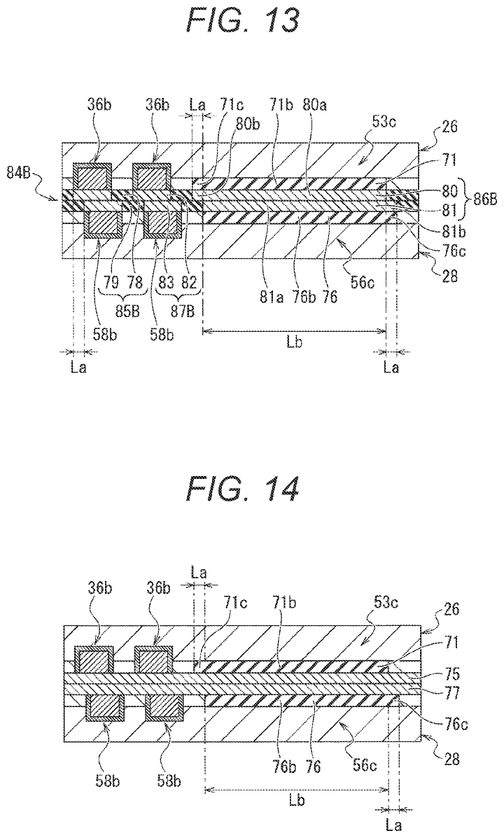

The bonding layer 84B includes an insulating layer 85B, a light shielding layer 86B, and a conducting layer 87B. The bonding layer 84B is obtained in a case where a bonding position between the first semiconductor substrate 26 side and the second semiconductor substrate 28 side is misaligned. FIG. 13 illustrates an example of such a misalignment and illustrates a case where there is a misalignment along the X direction between the first semiconductor substrate 26 side and the second semiconductor substrate 28 side by a distance La.

Due to the misalignment, the first antioxidant layer 71 and the second antioxidant layer 76 are partially misaligned in a case of being projected in the thickness direction, that is, in plan view. Then, the first antioxidant layer 71 and the second antioxidant layer 76 are aligned with each other in plan view except for the portion described above. The first antioxidant layer 71 includes a fourth portion 71b that is aligned with the second antioxidant layer 76 in plan view, and a fifth portion 71c that is misaligned with the second antioxidant layer 76 in plan view. Likewise, the second antioxidant layer 76 includes a fourth portion 76b that is aligned with the first antioxidant layer 71 in a case of being projected in the thickness direction, that is, in plan view, and a fifth portion 76c that is misaligned with the first antioxidant layer 71 in plan view.

The light shielding layer 86B is aligned with at least one of the first antioxidant layer 71 or the second antioxidant layer 76 in the thickness direction. The light shielding layer 86B includes a first light shielding layer 80 and a second light shielding layer 81. The first light shielding layer 80 includes a fourth portion 80a that is aligned with the second light shielding layer 81 in the thickness direction and a fifth portion 80b that is misaligned with the second light shielding layer 81 in the thickness direction. Likewise, the second light shielding layer 81 includes a fourth portion 81a that is aligned with the first light shielding layer 80 in the thickness direction and a fifth portion 81b that is misaligned with the second light shielding layer 81 in the thickness direction.

The fourth portion 80a of the first light shielding layer 80 is provided all over a surface of the fourth portion 71b of the first antioxidant layer 71 facing the surface S1, and a surface of the fourth portion 80a adjacent to the first semiconductor substrate 26 is in contact with the surface of the fourth portion 71b facing the surface S1. The fifth portion 80b of the first light shielding layer 80 is provided all over a surface of the fifth portion 71c of the first antioxidant layer 71 facing the surface S1, and a surface of the fifth portion 80b adjacent to the first semiconductor substrate 26 is in contact with the surface of the fifth portion 71c facing the surface S1.

The fourth portion 81a of the second light shielding layer 81 is provided all over a surface of the fourth portion 76b of the second antioxidant layer 76 facing the surface S2, and a surface of the fourth portion 81a adjacent to the second semiconductor substrate 28 is in contact with the surface of the fourth portion 76b facing the surface S2. The fifth portion 81b of the second light shielding layer 81 is provided all over a surface of the fifth portion 76c of the second antioxidant layer 76 facing the surface S2, and a surface of the fifth portion 81b adjacent to the second semiconductor substrate 28 is in contact with the surface of the fifth portion 76c facing the surface S2.

A length of the light shielding layer 86B in the X direction is equal to the sum of a length of the second light shielding layer 81 in the X direction (the sum of the distance La and a distance Lb) and a length of the fifth portion 80b of the first light shielding layer 80 in the X direction (distance La). Here, the second light shielding layer 81 is equal in length in the X direction to the first light shielding layer 80 and are both equal in length to the sum of the distance La and the distance Lb. As described above, the length and area of the light shielding layer 86B in the X direction increase in response to the misalignment by the distance La.

The conducting layer 87B includes a first conducting layer 82 and a second conducting layer 83. As illustrated in FIG. 13, the first conducting layer 82 and the second conducting layer 83 have portions aligned with each other in the thickness direction and portions misaligned with each other. The insulating layer 85B includes a first insulating layer 78 and a second insulating layer 79. The first insulating layer 78 and the second insulating layer 79 have portions aligned with each other in the thickness direction and portions misaligned with each other. The above is a configuration example of the solid-state imaging device 31.

<Example of Method for Manufacturing Solid-State Imaging Device>

Hereinafter, a method for manufacturing the solid-state imaging device 31 will be described with reference to the drawings. First, through the same process as in the first embodiment, the first semiconductor substrate 26 side and the second semiconductor substrate 28 side are prepared so as to cause their respective high melting point metal films to face each other. Then, as illustrated in FIG. 14, the first semiconductor substrate 26 side and second semiconductor substrate 28 side thus prepared are bonded together after alignment. As a result, the first high melting point metal film 75 and the second high melting point metal film 77 are bonded together. This, however, results in a misalignment between the first semiconductor substrate 26 side and the second semiconductor substrate 28 side by the distance La in the X direction.

Next, the first semiconductor substrate 26 and the second semiconductor substrate 28 bonded together by atomic diffusion are subjected to heat treatment. Under the heat treatment, a portion of the first high melting point metal film 75 that is in contact with the fourth portion 71b and the fifth portion 71c of the first antioxidant layer 71 is not oxidized and remains as titanium (Ti), thereby forming the first light shielding layer 80 in FIG. 13.

Here, the second high melting point metal film 77 is present between the portion of the first high melting point metal film 75 that is in contact with the fifth portion 71c and the second uppermost interlayer insulating film 56c of the second semiconductor substrate 28. Therefore, the portion of the first high melting point metal film 75 that is in contact with the fifth portion 71c and the second uppermost interlayer insulating film 56c of the second semiconductor substrate 28 are not in direct contact with each other and are separate from each other by a distance equivalent to the thickness of the second high melting point metal film 77. Thus, the portion of the first high melting point metal film 75 that is in contact with the fifth portion 71c is not oxidized and remains as titanium (Ti). Note that the second high melting point metal film 77 present between the portion of the first high melting point metal film 75 that is in contact with the fifth portion 71c and the second uppermost interlayer insulating film 56c of the second semiconductor substrate 28 is oxidized by heat treatment.

Likewise, a portion of the second high melting point metal film 77 that is in contact with the fourth portion 76b and the fifth portion 76c of the second antioxidant layer 76 is not oxidized and remains as titanium (Ti), thereby forming the second light shielding layer 81 in FIG. 13.

Here, the first high melting point metal film 75 is present between the portion of the second high melting point metal film 77 that is in contact with the fifth portion 76c and the first uppermost interlayer insulating film 53c of the first semiconductor substrate 26. Therefore, the portion of the second high melting point metal film 77 that is in contact with the fifth portion 76c and the first uppermost interlayer insulating film 53c of the first semiconductor substrate 26 are not in direct contact with each other and are separate from each other by a distance equivalent to the thickness of the first high melting point metal film 75. Thus, the portion of the second high melting point metal film 77 that is in contact with the fifth portion 76c is not oxidized and remains as titanium (Ti). Note that the first high melting point metal film 75 present between the portion of the second high melting point metal film 77 that is in contact with the fifth portion 76c and the first uppermost interlayer insulating film 53c of the first semiconductor substrate 26 is oxidized by heat treatment.

Furthermore, under the heat treatment, a portion of the first high melting point metal film 75 that is in contact with the first connecting pad 36b is not oxidized and remains as titanium (Ti), thereby forming the first conducting layer 82 in FIG. 13. Likewise, a portion of the second high melting point metal film 77 that is in contact with the second connecting pad 58b is not oxidized and remains as titanium (Ti), thereby forming the second conducting layer 83 in FIG. 13.

Furthermore, under the heat treatment, a portion of the first high melting point metal film 75 that is not in contact with either the first antioxidant layer 71 or the first connecting pad 36b is oxidized to become titanium dioxide (TiO₂), thereby forming the first insulating layer 78 in FIG. 13. Likewise, a portion of the second high melting point metal film 77 that is not in contact with either the second antioxidant layer 76 or the second connecting pad 58b is oxidized to become titanium dioxide (TiO₂), thereby forming the second insulating layer 79 in FIG. 13. The above is an example of the method for manufacturing the solid-state imaging device 31.

<Effect>

The solid-state imaging device 31 according to the modification 2 of the first embodiment produces effects similar to the effects produced by the solid-state imaging device 31 according to the first embodiment described above. Moreover, the insulating layer 85B prevents an electrode material from diffusing from the portion where the connecting pads are misaligned with each other.

Furthermore, in the solid-state imaging device 31 according to the modification 2 of the first embodiment, even in a case where a bonding misalignment occurs between the first semiconductor substrate 26 side and the second semiconductor substrate 28 side, the area of the light shielding layer 86B increases in response to the misalignment, so that it is possible to suppress passage of noise such as electromagnetic waves between the first semiconductor substrate 26 side and the second semiconductor substrate 28 side while improving the bonding strength between the first semiconductor substrate 26 side and the second semiconductor substrate 28 side.

<Modification 3 of First Embodiment>

<Configuration Example of Solid-State Imaging Device>

A modification 3 of the first embodiment of the present technology will be described below. The modification 3 of the first embodiment is different from the above-described first embodiment in that a bonding layer 84C is provided instead of the bonding layer 84 and only the first antioxidant layer 71 is provided, and the other configuration of the solid-state imaging device 31 is basically similar to the configuration of the solid-state imaging device 31 of the first embodiment described above.

[Configuration Example of Bonding Layer]

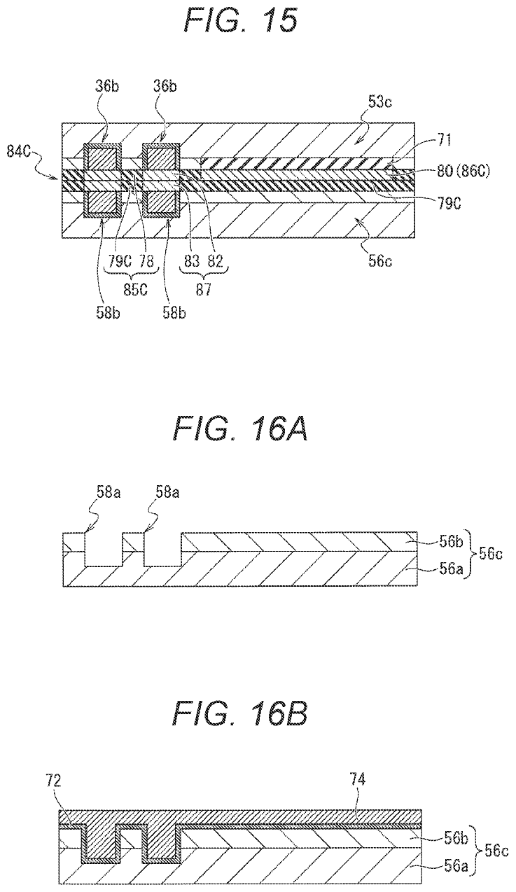

As illustrated in FIG. 15, the bonding layer 84C includes an insulating layer 85C, a light shielding layer 86C, and a conducting layer 87. The insulating layer 85C includes a first insulating layer 78 and a second insulating layer 79C. The light shielding layer 86C includes a first light shielding layer 80, but does not include the second light shielding layer 81 of the first embodiment. Furthermore, the antioxidant layer is provided only in the first semiconductor substrate 26 (first antioxidant layer 71), and is not provided in the second semiconductor substrate 28.

The light shielding layer 86C is provided at a position that is in perfect alignment with the first antioxidant layer 71 in plan view and is perfectly aligned with the first antioxidant layer 71 in the thickness direction. Specifically, the light shielding layer 86C is provided all over a surface of the first antioxidant layer 71 facing the surface S1, and a surface of the light shielding layer 86C adjacent to the first semiconductor substrate 26 is in contact with the surface of the first antioxidant layer 71 facing the surface S1.

Furthermore, the light shielding layer 86C, that is, a surface of the first light shielding layer 80 adjacent to the second semiconductor substrate 28 is in contact with the second light shielding layer 81 in the first embodiment, but in the modification 3 of the first embodiment, the second light shielding layer 81 is not provided, and the light shielding layer 86C is in contact with the second insulating layer 79C. A surface of the second insulating layer 79C adjacent to the second semiconductor substrate 28, the second insulating layer 79C being in contact with the light shielding layer 86C, is in contact with the second uppermost interlayer insulating film 56c of the second semiconductor substrate 28. Since the second insulating layer 79C has a portion formed between the light shielding layer 86C and the second uppermost interlayer insulating film 56c as described above, the second insulating layer 79C is provided over a wider range than the second insulating layer 79 of the first embodiment. The above is a configuration example of the solid-state imaging device 31.

<Example of Method for Manufacturing Solid-State Imaging Device>

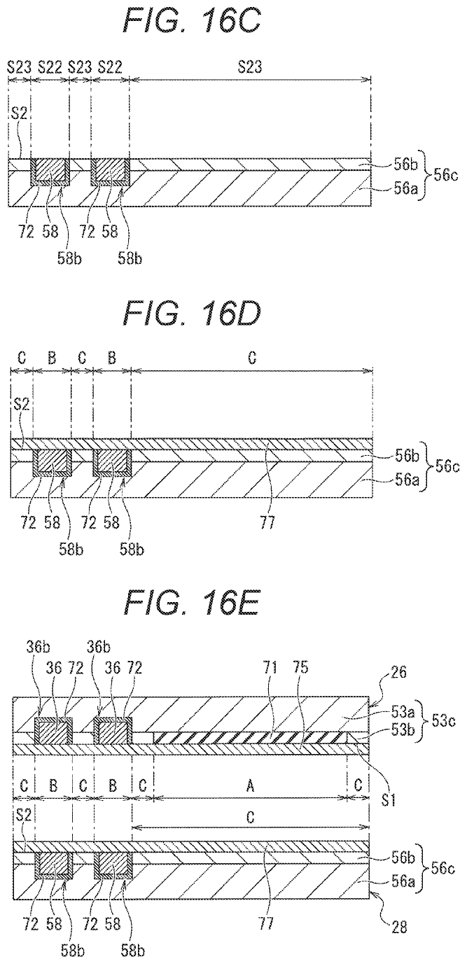

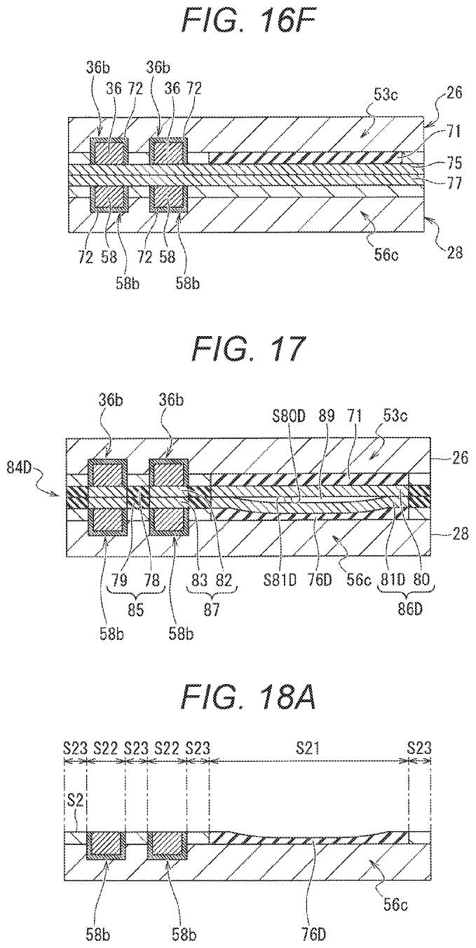

Hereinafter, a method for manufacturing the solid-state imaging device 31 will be described with reference to the drawings. Here, the antioxidant layer is provided only in the first semiconductor substrate 26 side. Since the method for manufacturing the first semiconductor substrate 26 side has already been described in the first embodiment, no detailed description of the method will be given here. Then, a method for manufacturing the second semiconductor substrate 28 side without providing the antioxidant layer will be described with reference to FIGS. 16A to 16D. First, as illustrated in FIG. 16A, the wiring groove 58a is formed in the second uppermost interlayer insulating film 56c by lithography and etching.

Then, as illustrated in FIG. 16B, the Cu diffusion barrier metal film 72 is formed to cover the second uppermost interlayer insulating film 56c in which the wiring groove 58a is formed. Thereafter, as illustrated in FIG. 16B, the Cu material layer 74 is embedded, by plating, in the wiring groove 58a in which the Cu diffusion barrier metal film 72 is formed.

Next, unnecessary portions of the Cu material layer 74, the Cu diffusion barrier metal film 72, and the second uppermost interlayer insulating film 56c are removed by CMP. As a result, as illustrated in FIG. 16C, the planarized surface S2 is obtained, and the second connecting pad 58b is formed. Then, the surface S2 includes a surface S22 of the second connecting pad 58b facing the surface S2, and a surface S23 of the second uppermost interlayer insulating film 56c facing the surface S2.

Next, as illustrated in FIG. 16D, the second high melting point metal film 77 is formed to cover the surface S2 of the second semiconductor substrate 28 obtained as described above. Here, of the second high melting point metal film 77, a portion that is in contact with the surface S22 is referred to as a second portion B, a portion that is in contact with the surface S23 is referred to as a third portion C. As described above, the second semiconductor substrate 28 side is obtained. The first semiconductor substrate 26 side is further obtained by the manufacturing method described in the first embodiment.

Next, as illustrated in FIG. 16E, the first semiconductor substrate 26 side and the second semiconductor substrate 28 side are prepared so as to cause their respective high melting point metal films to face each other. At this time, the first semiconductor substrate 26 side and the second semiconductor substrate 28 side are aligned so as to cause the second portion B of the first semiconductor substrate 26 side and the second portion B of the second semiconductor substrate 28 side to align with each other and cause the third portion C of the first semiconductor substrate 26 side and the third portion C of the second semiconductor substrate 28 side to align with each other in the thickness direction. Here, since the second semiconductor substrate 28 side has no first portion A, the first portion A of the first semiconductor substrate 26 side is aligned with the third portion C of the second semiconductor substrate 28 side.

Next, as illustrated in FIG. 16F, the first semiconductor substrate 26 side and the second semiconductor substrate 28 side are placed on top of each other so as to bring their respective high melting point metal films into contact with each other. As a result, their respective high melting point metal films are bonded together to form a single body.

Next, the first semiconductor substrate 26 and the second semiconductor substrate 28 bonded together by atomic diffusion are subjected to heat treatment. Under the heat treatment, the first portion A of the first high melting point metal film 75 is not oxidized and remains as titanium (Ti), thereby forming the first light shielding layer 80 in FIG. 15. Here, the antioxidant layer is not formed in the second semiconductor substrate 28, but the second high melting point metal film 77 is present between the first portion A of the first high melting point metal film 75 and the second uppermost interlayer insulating film 56c of the second semiconductor substrate 28. Therefore, the first portion A of the first high melting point metal film 75 and the second uppermost interlayer insulating film 56c of the second semiconductor substrate 28 are not in direct contact with each other and are separate from each other by a distance equivalent to the thickness of the second high melting point metal film 77. Thus, the first portion A of the first high melting point metal film 75 is not oxidized and remains as titanium (Ti). Note that the second high melting point metal film 77 present between the first portion A of the first high melting point metal film 75 and the second uppermost interlayer insulating film 56c of the second semiconductor substrate 28 is oxidized by heat treatment.

Furthermore, under the heat treatment, the second portion B of the first high melting point metal film 75 is not oxidized and remains as titanium (Ti), thereby forming the first conducting layer 82 in FIG. 15. Likewise, the second portion B of the second high melting point metal film 77 is not oxidized and remains as titanium (Ti), thereby forming the second conducting layer 83 in FIG. 15.

Furthermore, under the heat treatment, the third portion C of the first high melting point metal film 75 is oxidized to become titanium dioxide (TiO₂), thereby forming the first insulating layer 78 in FIG. 15. Likewise, the third portion C of the second high melting point metal film 77 is oxidized to become titanium dioxide (TiO₂), thereby forming the second insulating layer 79 in FIG. 15. The above is an example of the method for manufacturing the solid-state imaging device 31.

<Effect>

The solid-state imaging device 31 according to the modification 3 of the first embodiment produces effects similar to the effects produced by the solid-state imaging device 31 according to the first embodiment described above.

Furthermore, in the solid-state imaging device 31 according to the modification 3 of the first embodiment, the first antioxidant layer 71 is provided only in the first semiconductor substrate 26, which eliminates the need of the process of manufacturing the second semiconductor substrate 28.

Note that the antioxidant layer is provided only in the first semiconductor substrate 26, but may be provided only in the second semiconductor substrate 28. The antioxidant layer may be provided in only either the first semiconductor substrate 26 or the second semiconductor substrate 28.

In a case where the antioxidant layer is provided only in the second semiconductor substrate 28, the light shielding layer 86C is provided at a position that is in perfect alignment with the second antioxidant layer 76 in plan view and is perfectly aligned with the second antioxidant layer 76 in the thickness direction. Specifically, the light shielding layer 86C is provided all over a surface of the second antioxidant layer 76 facing the surface S2, and a surface of the light shielding layer 86C adjacent to the second semiconductor substrate 28 is in contact with the surface of the second antioxidant layer 76 facing the surface S2.

<Modification 4 of First Embodiment>

<Configuration Example of Solid-State Imaging Device>

A modification 4 of the first embodiment of the present technology will be described below. The modification 4 of the first embodiment is different from the above-described first embodiment in that a bonding layer 84D is provided instead of the bonding layer 84 and the second antioxidant layer 76D has a dishing shape, and the other configuration of the solid-state imaging device 31 is basically similar to the configuration of the solid-state imaging device 31 of the first embodiment described above.

[Configuration Example of Bonding Layer]

As illustrated in FIG. 17, the bonding layer 84D includes an insulating layer 85, a light shielding layer 86D, a conducting layer 87, and a gap 89. The light shielding layer 86D includes a first light shielding layer 80 and a second light shielding layer 81D. The first semiconductor substrate 26 is provided with a first antioxidant layer 71, and the second semiconductor substrate 28 is provided with a second antioxidant layer 76D.

A surface of the second antioxidant layer 76D facing the surface S2 has a dishing shape. The surface of the second antioxidant layer 76D facing the surface S2 has a shape in which a center portion in a direction orthogonal to the thickness direction is dished toward the second semiconductor substrate 28. As described above, dishing may occur in a manner that depends on the CMP condition, other conditions, or the like.

The second light shielding layer 81D is provided at a position that is in perfect alignment with the second antioxidant layer 76D in plan view and is perfectly aligned with the second antioxidant layer 76D in the thickness direction. Specifically, the second light shielding layer 81D is provided all over the surface of the second antioxidant layer 76D facing the surface S2, and a surface of the second light shielding layer 81D adjacent to the second antioxidant layer 76D is in contact with the surface of the second antioxidant layer 76D facing the surface S2. Here, a surface of the second light shielding layer 81D remote from the second antioxidant layer 76D, that is, a surface of the second light shielding layer 81D adjacent to the first semiconductor substrate 26 is referred to as a surface S81D.

Since the second antioxidant layer 76D has a dishing shape, the second light shielding layer 81D is also provided along the dishing shape of the second antioxidant layer 76D. The second light shielding layer 81D has a shape in which a center portion in a direction orthogonal to the thickness direction is dished toward the second semiconductor substrate 28. Therefore, a center portion of a surface (hereinafter, referred to as a surface S80D) of the first light shielding layer 80 adjacent to the second semiconductor substrate 28, that is, a surface remote from the first antioxidant layer 71, and the center portion of S81D of the second light shielding layer 81D are provided apart from each other in the thickness direction and are not in contact with each other. Therefore, in the center portion in the direction orthogonal to the thickness direction, the gap 89 is provided between the first light shielding layer 80 adjacent to the first semiconductor substrate 26 and the second light shielding layer 81D adjacent to the second semiconductor substrate 28. As described above, the first light shielding layer 80 and the second light shielding layer 81D have portions in contact with each other in the thickness direction and have portions out of contact with each other.

<Example of Method for Manufacturing Solid-State Imaging Device>

Hereinafter, a method for manufacturing the solid-state imaging device 31 will be described with reference to the drawings. Since the method for manufacturing the first semiconductor substrate 26 side has already been described in the first embodiment, no detailed description of the method will be given here. Hereinafter, a method for manufacturing the second semiconductor substrate 28 side will be described. Note that no detailed description will be given of the same process as in the first embodiment.

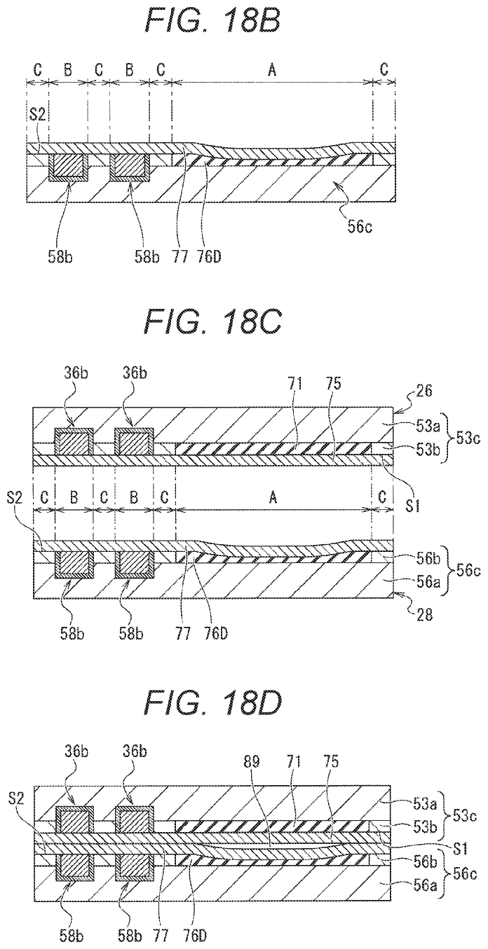

First, as illustrated in FIG. 8F of the first embodiment, the second antioxidant layer 76, the wiring groove 58a, the Cu diffusion barrier metal film 72, and the Cu material layer 74 are sequentially formed. Next, as illustrated in FIG. 18A, unnecessary portions of the Cu diffusion barrier metal film 72, the Cu material layer 74, and the second uppermost interlayer insulating film 56c are removed by CMP to obtain the second connecting pad 58b and the surface S2 of the second semiconductor substrate 28. The second antioxidant layer 76 has a surface facing the surface S2 subjected to dishing by CMP to become the second antioxidant layer 76D. Then, the surface S2 includes a surface S21 of the second antioxidant layer 76D facing the surface S2, a surface S22 of the second connecting pad 58b facing the surface S2, and a surface S23 of the second uppermost interlayer insulating film 56c facing the surface S2.

Next, as illustrated in FIG. 18B, the second high melting point metal film 77 is formed to cover the surface S2 of the second semiconductor substrate 28. Here, of the second high melting point metal film 77, a portion that is in contact with the surface S21 is referred to as a first portion A, a portion that is in contact with the surface S22 is referred to as a second portion B, and a portion that is in contact with the surface S23 is referred to as a third portion C. As described above, the second semiconductor substrate 28 side is obtained.

Next, as illustrated in FIG. 18C, the first semiconductor substrate 26 side and the second semiconductor substrate 28 side are prepared so as to cause their respective high melting point metal films to face each other. At this time, the first semiconductor substrate 26 side and the second semiconductor substrate 28 side are aligned so as to cause the first portion A of the first semiconductor substrate 26 side and the first portion A of the second semiconductor substrate 28 side to align with each other, cause the second portion B of the first semiconductor substrate 26 side and the second portion B of the second semiconductor substrate 28 to align with each other, and cause the third portion C of the first semiconductor substrate 26 side and the third portion C of the second semiconductor substrate 28 side to align with each other in the thickness direction.

Next, as illustrated in FIG. 18D, the first semiconductor substrate 26 side and the second semiconductor substrate 28 side are placed on top of each other so as to bring their respective high melting point metal films into contact with each other. As a result, their respective high melting point metal films are bonded together to form a single body. The first light shielding layer 80 and the second light shielding layer 81D, however, have portions out of contact with each other in the thickness direction. As a result, the gap 89 is formed.

Then, the first semiconductor substrate 26 and the second semiconductor substrate 28 in FIG. 18D are subjected to heat treatment to form the solid-state imaging device 31 illustrated in FIG. 17. The above is an example of the method for manufacturing the solid-state imaging device 31.

<Effect>

The solid-state imaging device 31 according to the modification 4 of the first embodiment produces effects similar to the effects produced by the solid-state imaging device 31 according to the first embodiment described above.

Furthermore, the solid-state imaging device 31 according to the modification 4 of the first embodiment allows a reduction in load of planarization after the Cu material layer 74 is formed.

Note that the second antioxidant layer 76D has a dishing shape, but the first antioxidant layer 71 may have a dishing shape. In this case, the first light shielding layer 80 is also provided along the dishing shape of the first antioxidant layer 71. Moreover, both the second antioxidant layer 76D and the first antioxidant layer 71 may have a dishing shape.

Furthermore, the degree of dishing in FIGS. 17 and 18A to 18D is shown in an exaggerated manner, and the actual degree of dishing is not limited to such a degree.

### Second Embodiment

<Configuration Example of Solid-State Imaging Device>

A second embodiment of the present technology will be described below. The second embodiment is different from the first embodiment described above in that a bonding layer 84E is provided instead of the bonding layer 84, a first antioxidant layer 71E is provided instead of the first antioxidant layer 71, and a second antioxidant layer 76E is provided instead of the second antioxidant layer 76, and other configuration of the solid-state imaging device 31 is basically similar to the configuration of the solid-state imaging device 31 of the first embodiment described above.

[Configuration Example of Bonding Layer]

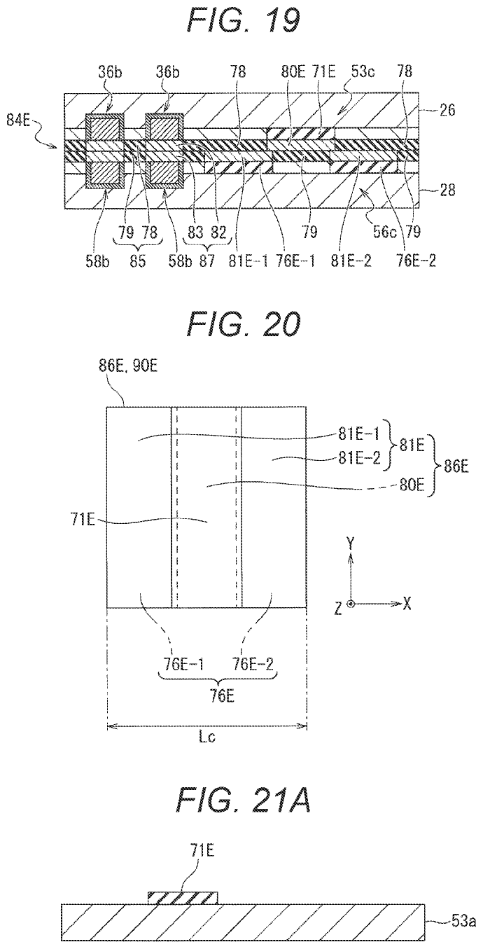

As illustrated in FIGS. 19 and 20, the bonding layer 84E includes an insulating layer 85, a light shielding layer 86E, and a conducting layer 87. The light shielding layer 86E includes a first light shielding layer 80E adjacent to the first semiconductor substrate 26 and a second light shielding layer 81E adjacent to the second semiconductor substrate 28.

The first antioxidant layer 71E is an antioxidant layer provided in the first semiconductor substrate 26 and includes a substance (insulating film) that is lower in hygroscopicity than the first uppermost interlayer insulating film 53c. The second antioxidant layer 76E is an antioxidant layer provided in the second semiconductor substrate 28, includes a substance (insulating film) that is lower in hygroscopicity than the second uppermost interlayer insulating film 56c, and includes a second antioxidant layer 76E-1 and a second antioxidant layer 76E-2.

The first antioxidant layer 71E and the second antioxidant layer 76E are provided alternately (in a staggered arrangement) along a direction orthogonal to the thickness direction. FIGS. 19 and 20 illustrate an example where the first antioxidant layer 71E and the second antioxidant layer 76E are alternately provided along the X direction. Specifically, the second antioxidant layer 76E-1, the first antioxidant layer 71E, and the second antioxidant layer 76E-2 are provided in this order from the conducting layer 87 side along the X direction.

FIG. 20 is a plan view of the light shielding layer 86E, the first antioxidant layer 71E, and the second antioxidant layer 76E observed from above the first semiconductor substrate 26. The first antioxidant layer 71E and the second antioxidant layer 76E are provided apart from each other in the thickness direction, but, in plan view, appear to overlap as illustrated in FIG. 20. A region occupied by the first antioxidant layer 71E and the second antioxidant layer 76E in this plan view is referred to as an antioxidant layer formation region 90E. As described above, the antioxidant layer formation region 90E is a region occupied by a plurality of antioxidant layers that is provided apart from each other in the thickness direction, the plurality of antioxidant layers each being smaller in area than the antioxidant layer formation region 90E in plan view. Furthermore, as illustrated in FIG. 20, the antioxidant layer formation region 90E has a square shape with a side length Lc in plan view.

A distance in the X direction between the second antioxidant layer 76E-1 and the second antioxidant layer 76E-2 is set smaller than the width of the first antioxidant layer 71E in the X direction. The second antioxidant layer 76E-1 and the first antioxidant layer 71E overlap in a case of being projected in the thickness direction, that is, in plan view. The second antioxidant layer 76E-1 and the first antioxidant layer 71E have portions aligned with each other and portions misaligned with each other in plan view. Moreover, the first antioxidant layer 71E and the second antioxidant layer 76E-2 overlap in a case of being projected in the thickness direction, that is, in plan view. The first antioxidant layer 71E and the second antioxidant layer 76E-2 have portions aligned with each other and portions misaligned with each other in plan view. In plan view, the first antioxidant layer 71E, the second antioxidant layer 76E-1, and the second antioxidant layer 76E-2, which are the plurality of antioxidant layers, occupy the antioxidant layer formation region 90E without any gap while overlapping in plan view.

As illustrated in FIG. 20, the first antioxidant layer 71E, the second antioxidant layer 76E-1, and the second antioxidant layer 76E-2 each has a rectangular shape in plan view. A length in the X direction of each of the first antioxidant layer 71E, the second antioxidant layer 76E-1, and the second antioxidant layer 76E-2 is smaller than the side length Lc of the antioxidant layer formation region 90E, and a length in the Y direction is equal to the length Lc. The first antioxidant layer 71E, the second antioxidant layer 76E-1, and the second antioxidant layer 76E-2 are equal in length in the X direction to each other.

The second light shielding layer 81E includes a second light shielding layer 81E-1 and a second light shielding layer 81E-2. The second light shielding layer 81E-1 is provided at a position that is in perfect alignment with the second antioxidant layer 76E-1 in plan view and is perfectly aligned with the second antioxidant layer 76E-1 in the thickness direction. Specifically, the second light shielding layer 81E-1 is provided all over a surface of the second antioxidant layer 76E-1 facing the surface S2, and a surface of the second light shielding layer 81E-1 adjacent to the second antioxidant layer 76E-1 is in contact with the surface of the second antioxidant layer 76E-1 facing the surface S2.

The first light shielding layer 80E is provided at a position that is in perfect alignment with the first antioxidant layer 71E in plan view and is perfectly aligned with the first antioxidant layer 71E in the thickness direction. Specifically, the first light shielding layer 80E is provided all over a surface of the first antioxidant layer 71E facing the surface S1, and a surface of the first light shielding layer 80E adjacent to the first semiconductor substrate 26 is in contact with the surface of the first antioxidant layer 71E facing the surface S1.

The second light shielding layer 81E-2 is provided at a position that is in perfect alignment with the second antioxidant layer 76E-2 in plan view and is perfectly aligned with the second antioxidant layer 76E-2 in the thickness direction. Specifically, the second light shielding layer 81E-2 is provided all over a surface of the second antioxidant layer 76E-2 facing the surface S2, and a surface of the second light shielding layer 81E-2 adjacent to the second antioxidant layer 76E-2 is in contact with the surface of the second antioxidant layer 76E-2 facing the surface S2.

The first light shielding layer 80E and the second light shielding layer 81E are alternately provided along a direction orthogonal to the thickness direction. Specifically, the second light shielding layer 81E-1, the first light shielding layer 80E, and the second light shielding layer 81E-2 are provided in this order from the conducting layer 87 side along the X direction.

The second light shielding layer 81E-1 and the first light shielding layer 80E overlap in plan view and in the thickness direction, and the overlapping portions are bonded together. Moreover, the first light shielding layer 80E and the second light shielding layer 81E-2 overlap in plan view and in the thickness direction, and the overlapping portions are bonded together. As illustrated in FIG. 20, the light shielding layer 86E has a square shape with the side length Lc in plan view. In plan view, the first light shielding layer 80E, the second light shielding layer 81E-1, and the second light shielding layer 81E-2 occupy the region of the light shielding layer 86E without any gap while overlapping along the X direction.

<Example of Method for Manufacturing Solid-State Imaging Device>

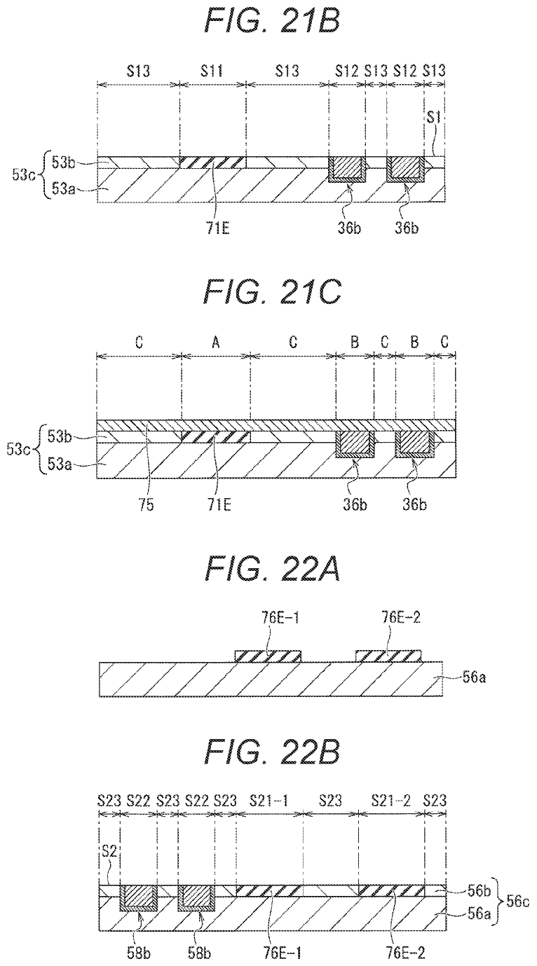

Hereinafter, a method for manufacturing the solid-state imaging device 31 will be described with reference to the drawings. First, the first semiconductor substrate 26 side will be described. As illustrated in FIG. 21A, the first antioxidant layer 71E is formed by lithography and etching. Then, as illustrated in FIG. 21B, the first connecting pad 36b and the surface S1 are formed. The surface S1 includes a surface S11 of the first antioxidant layer 71E facing the surface S1, a surface S12 of the first connecting pad 36b facing the surface S1, and a surface S13 of the first uppermost interlayer insulating film 53c facing the surface S1.

Next, as illustrated in FIG. 21C, the first high melting point metal film 75 is formed to cover the surface S1 of the first semiconductor substrate 26 obtained as described above. Of the first high melting point metal film 75, a portion that is in contact with the surface S11 is referred to as a first portion A, a portion that is in contact with the surface S12 is referred to as a second portion B, and a portion that is in contact with the surface S13 is referred to as a third portion C. As described above, the first semiconductor substrate 26 side is obtained.

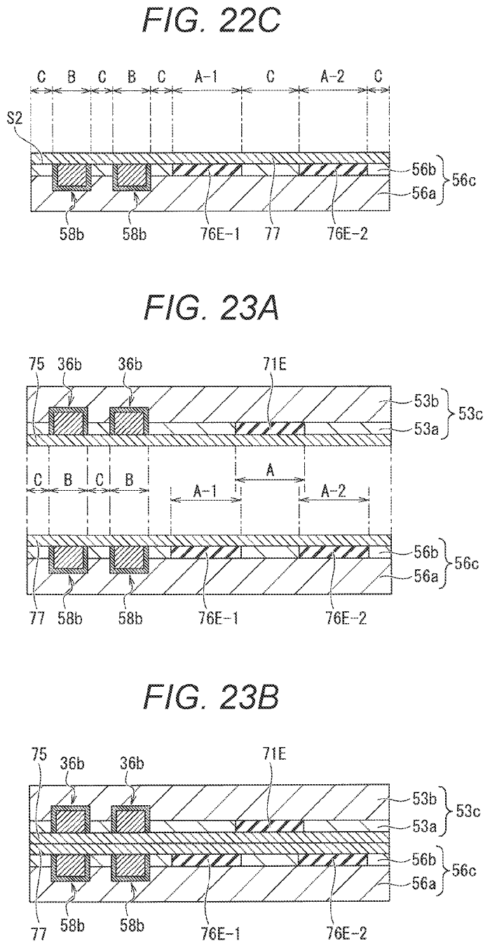

Next, the second semiconductor substrate 28 side will be described. As illustrated in FIG. 22A, the second antioxidant layers 76E-1 and 76E-2 are formed by lithography and etching. A distance in the X direction between the second antioxidant layer 76E-1 and the second antioxidant layer 76E-2 is set smaller than the width of the first antioxidant layer 71E in the X direction. Then, as illustrated in FIG. 22B, the second connecting pad 58b and the surface S2 are formed. The surface S2 includes a surface S21-1 of the second antioxidant layer 76E-1 facing the surface S2, a surface S21-2 of the second antioxidant layer 76E-2 facing the surface S2, a surface S22 of the second connecting pad 58b facing the surface S2, and a surface S23 of the second uppermost interlayer insulating film 56c facing the surface S2.

Next, as illustrated in FIG. 22C, the second high melting point metal film 77 is formed to cover the surface S2 of the second semiconductor substrate 28 obtained as described above. Of the second high melting point metal film 77, a portion that is in contact with the surface S21-1 is referred to as a first portion A-1, a portion that is in contact with the surface S21-2 is referred to as a first portion A-2, a portion that is in contact with the surface S22 is referred to as a second portion B, and a portion that is in contact with the surface S23 is referred to as a third portion C. As described above, the second semiconductor substrate 28 side is obtained.

Thereafter, as illustrated in FIG. 23A, the first semiconductor substrate 26 side and the second semiconductor substrate 28 side are prepared so as to cause their respective high melting point metal films to face each other. At this time, the first semiconductor substrate 26 side and the second semiconductor substrate 28 side are aligned so as to cause the second portion B of the first semiconductor substrate 26 side and the second portion B of the second semiconductor substrate 28 side to align with each other and cause the third portion C of the first semiconductor substrate 26 side and the third portion C of the second semiconductor substrate 28 side to align with each other in the thickness direction. Here, the distance in the X direction between the second antioxidant layer 76E-1 and the second antioxidant layer 76E-2 is set smaller than the width of the first antioxidant layer 71E in the X direction. Therefore, a margin, in plan view, of the overlapping between the first antioxidant layer 71E and the second antioxidant layer 76E in the X direction is set large.

Next, as illustrated in FIG. 23B, the first semiconductor substrate 26 side and the second semiconductor substrate 28 side are placed on top of each other so as to bring their respective high melting point metal films into contact with each other. As a result, their respective high melting point metal films are bonded together to form a single body. Then, the first semiconductor substrate 26 and the second semiconductor substrate 28 in FIG. 23B are subjected to heat treatment to form the solid-state imaging device 31 illustrated in FIG. 19. The above is an example of the method for manufacturing the solid-state imaging device 31.

<Effect>

The solid-state imaging device 31 according to the second embodiment produces effects similar to the effects produced by the solid-state imaging device 31 according to the first embodiment described above.

Furthermore, since the solid-state imaging device 31 according to the second embodiment includes the plurality of antioxidant layers each having a small area, it is possible to reduce and suppress dishing of the antioxidant layers during planarization after the Cu material layer 74 is formed. It is therefore possible to bring the first semiconductor substrate 26 side and the second semiconductor substrate 28 side into contact with each other more reliably and to suppress passage of noise such as electromagnetic waves between the first semiconductor substrate 26 side and the second semiconductor substrate 28 side while improving the bonding strength between the first semiconductor substrate 26 side and the second semiconductor substrate 28 side.

Furthermore, in the solid-state imaging device 31 according to the second embodiment, when the second antioxidant layer 76E-1, the first antioxidant layer 71E, and the second antioxidant layer 76E-2 are provided so as to overlap in plan view, it is possible to absorb a bonding misalignment between the first semiconductor substrate 26 side and the second semiconductor substrate 28 side in a case of being projected in the thickness direction, that is, in plan view. As a result, the first light shielding layer 80E, the second light shielding layer 81E-1, and the second light shielding layer 81E-2 can occupy, while overlapping, the region of the light shielding layer 86E without any gap.

Note that the first antioxidant layer 71E, the second antioxidant layer 76E-1, and the second antioxidant layer 76E-2 are set equal in length in the X direction to each other, but may be set different in length from each other. In this case, the first light shielding layer 80E, the second light shielding layer 81E-1, and the second light shielding layer 81E-2 are also set different in length in the X direction from each other.

Furthermore, the first antioxidant layer 71E, the second antioxidant layer 76E-1, and the second antioxidant layer 76E-2 are alternately provided along the X direction, but may be alternately provided along the Y direction. In this case, the first light shielding layer 80E, the second light shielding layer 81E-1, and the second light shielding layer 81E-2 are alternately provided along the Y direction to occupy, while overlapping, the region of the light shielding layer 86E without any gap.

Furthermore, the distance in the X direction between the second antioxidant layer 76E-1 and the second antioxidant layer 76E-2 is set smaller than the width of the first antioxidant layer 71E in the X direction, but may be set equal to the width of the first antioxidant layer 71E in the X direction. In this case, the first light shielding layer 80E, the second light shielding layer 81E-1, and the second light shielding layer 81E-2 do not overlap along the Y direction and occupy the region of the light shielding layer 86E without any gap. This is effective in a case where there is no or only a small bonding misalignment between the first semiconductor substrate 26 side and the first semiconductor substrate 26 side.

Furthermore, the second antioxidant layer 76E includes the plurality of antioxidant layers: the second antioxidant layer 76E-1 and the second antioxidant layer 76E-2, but the first antioxidant layer 71E may include a plurality of antioxidant layers. In this case, the light shielding layer 86E includes a plurality of first light shielding layers 80E and one second light shielding layer 81E.

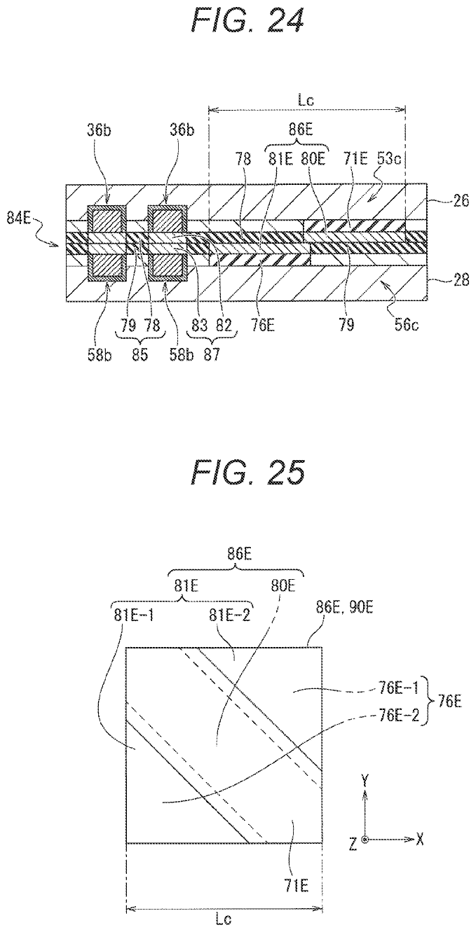

Furthermore, the antioxidant layer formation region 90E is occupied by the three antioxidant layers: the first antioxidant layer 71E, the second antioxidant layer 76E-1, and the second antioxidant layer 76E-2, but may be occupied by two antioxidant layers: the first antioxidant layer 71E and the second antioxidant layer 76E as in another example illustrated in FIG. 24. In this case, the light shielding layer 86E includes two light shielding layers: the first light shielding layer 80E and the second light shielding layer 81E. Then, the first light shielding layer 80E and the second light shielding layer 81E are alternately provided along the X direction to occupy, while overlapping, the region of the light shielding layer 86E without any gap. Moreover, the first antioxidant layer 71E may include two or more antioxidant layers, the second antioxidant layer 76E may include two or more antioxidant layers, and the first antioxidant layer 71E and the second antioxidant layer 76E may be alternately provided. In this case, the first light shielding layer 80E includes a plurality of light shielding layers, the second light shielding layer 81E includes a plurality of light shielding layers, and the first light shielding layer 80E and the second light shielding layer 81E are alternately provided.

Furthermore, the first antioxidant layer 71E, the second antioxidant layer 76E-1, and the second antioxidant layer 76E-2 are alternately provided along the X direction, but may be alternately provided along a direction oblique to the X direction as in another example illustrated in FIG. 25. The direction oblique to the X direction is a direction that forms an angle smaller than 90 degrees with the X direction. In this case, the first light shielding layer 80E, the second light shielding layer 81E-1, and the second light shielding layer 81E-2 are alternately provided along the direction oblique to the X direction to occupy, while overlapping, the region of the light shielding layer 86E without any gap.

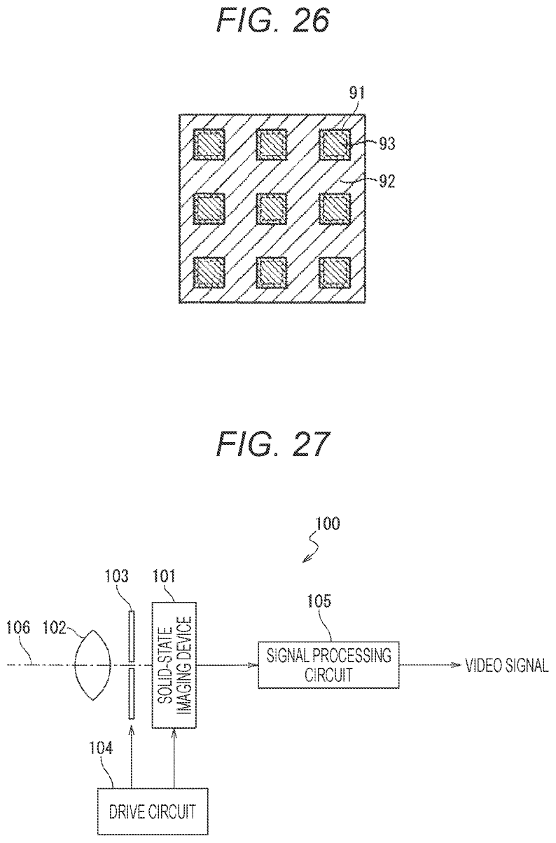

Furthermore, as in another example illustrated in FIG. 26, either the first antioxidant layer 71E or the second antioxidant layer 76E, in this example, the first antioxidant layer 71E may be formed in a shape 92 having a plurality of openings 91 provided at predetermined pitches in the vertical and horizontal directions as viewed from above; on the other hand, in this example, the second antioxidant layer 76E may be provided as dots 93 that occupy the openings 91 of the first antioxidant layer 71E as viewed from above. The antioxidant layer formation region 90E in plan view is occupied without any gap by the first antioxidant layer 71E and the second antioxidant layer 76E provided apart from each other in the thickness direction.

Likewise, either the first light shielding layer 80E or the second light shielding layer 81E, in this example, the first light shielding layer 80E, may be formed in the shape 92 having the plurality of openings 91 provided at predetermined pitches in the vertical and horizontal directions as viewed from above; on the other hand, in this example, the second light shielding layer 81E may be provided as the dots 93 that occupy the openings 91 of the first light shielding layer 80E as viewed from above. The region of the light shielding layer 86E in plan view is occupied without any gap by the first light shielding layer 80E and the second light shielding layer 81E that are partially bonded.

### Third Embodiment: Electronic Instrument

Next, an electronic instrument according to a third embodiment of the present technology will be described. FIG. 27 is a configuration diagram schematically illustrating an electronic instrument 100 according to the third embodiment of the present technology.

The electronic instrument 100 according to the third embodiment includes a solid-state imaging device 101, an optical lens 102, a shutter device 103, a drive circuit 104, and a signal processing circuit 105. The electronic instrument 100 according to the third embodiment indicates an embodiment in a case where the solid-state imaging device 31 according to any one of the first embodiment, the modifications of the first embodiment, or the second embodiment of the present technology is used, as the solid-state imaging device 101, in an electronic instrument (for example, a camera).

The optical lens 102 forms an image of image light (incident light 106) from a subject on an imaging surface of the solid-state imaging device 101. As a result, signal charges are accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. The signal transfer of the solid-state imaging device 101 is performed by a drive signal (timing signal) supplied from the drive circuit 104. The signal processing circuit 105 performs various types of signal processing on a signal (pixel signal) output from the solid-state imaging device 101. A video signal subjected to the signal processing is stored in a storage medium such as a memory or output to a monitor.

Note that the electronic instrument 100 to which the solid-state imaging device 31 can be applied is not limited to a camera, and the solid-state imaging device 31 can also be applied to other electronic instruments. For example, the solid-state imaging device 31 may be applied to an imaging device such as a camera module for a mobile device such as a mobile phone or a tablet terminal.

### Other Embodiments

While the present technology has been described above by way of the first to third embodiments and the modifications of the embodiments, it should not be understood that the description and drawings constituting a part of this disclosure limit the present technology. Various alternative embodiments, examples, and operation techniques will be apparent to those skilled in the art from this disclosure.

Furthermore, the technical ideas described in the first to third embodiments and the modifications of the embodiments may be combined with each other. For example, various combinations in accordance with each technical idea are possible, such as application of the technical idea according to the bonding layer 84B in a case where there is a misalignment described in the modification 2 of the first embodiment to the bonding layer 84E according to the second embodiment.

As described above, it is a matter of course that the present technology includes various embodiments and the like not described herein. Therefore, the technical scope of the present technology is defined only by the matters used to define the invention described in the claims considered appropriate from the above description.

Furthermore, in the first embodiment, the modifications 1 to 4 of the first embodiment, and the second embodiment described above, the light shielding layer is provided all over the projection surface of the pixel region 34 in plan view, but the light shielding layer may be provided over a part of the projection surface of the pixel region 34. In this case, the light shielding layer may be provided between a region where more noise is produced, such as a signal readout circuit of the second semiconductor substrate 28, and the pixel region 34 of the first semiconductor substrate 26.

Furthermore, in the first embodiment, the modifications 1 to 4 of the first embodiment, and the second embodiment described above, the first antioxidant layer, the second antioxidant layer, and the antioxidant layer formation region 90E each have a square shape, but may have a different shape such as a rectangular shape.

Furthermore, in the first embodiment, the modifications 1 to 4 of the first embodiment, and the second embodiment, the first high melting point metal film 75 is provided on the surface S1 of the multilayer wiring layer 37. That is, the first high melting point metal film 75 is not included in the multilayer wiring layer 37. The first high melting point metal film 75, however, may be included in the multilayer wiring layer 37. In this case, when a description will be given of each part of the first high melting point metal film 75 after heat treatment with reference to, for example, the first embodiment as an example, the first insulating layer 78, the first light shielding layer 80, and the first conducting layer 82 illustrated in FIG. 4B are also included in the multilayer wiring layer 37.

Moreover, in the first embodiment, the modifications 1 to 4 of the first embodiment, and the second embodiment described above, the second high melting point metal film 77 is provided on the surface S2 of the multilayer wiring layer 59. That is, the second high melting point metal film 77 is not included in the multilayer wiring layer 59. The second high melting point metal film 77, however, may be included in the multilayer wiring layer 59. In this case, when a description will be given of each part of the second high melting point metal film 77 after heat treatment with reference to, for example, the first embodiment as an example, the second insulating layer 79, the second light shielding layer 81, and the second conducting layer 83 illustrated in FIG. 4B are also included in the multilayer wiring layer 59.

A bonding surface between the multilayer wiring layer 37 including the first high melting point metal film 75 and the multilayer wiring layer 59 including the second high melting point metal film 77 as described above is a bonding surface S3 illustrated in FIG. 4B when described with reference to, for example, the first embodiment as an example. Then, the first insulating layer 78, the first light shielding layer 80, and the first conducting layer 82 included in the multilayer wiring layer 37, and the second insulating layer 79, the second light shielding layer 81, and the second conducting layer 83 included in the multilayer wiring layer 59 are exposed to the bonding surface S3.

Furthermore, the effects described herein are merely illustrative and not restrictive, and may have additional effects.

Note that the present technology may have the following configurations.

(1)

A solid-state imaging device including:
a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface;
a second semiconductor substrate including a second semiconductor layer in which a circuit is formed and a second multilayer wiring layer including an interlayer insulating film formed on a side of the second semiconductor layer adjacent to the light incident surface, the second multilayer wiring layer being bonded to the first multilayer wiring layer;
a light shielding layer provided in at least one of the first multilayer wiring layer or the second multilayer wiring layer so as to be exposed to a bonding surface between the first multilayer wiring layer and the second multilayer wiring layer; and
an antioxidant layer provided in at least one of the first multilayer wiring layer or the second multilayer wiring layer and provided at least either between the light shielding layer and the interlayer insulating film of the first multilayer wiring layer or between the light shielding layer and the interlayer insulating film of the second multilayer wiring layer.
   (2)

In the solid-state imaging device according to (1), the light shielding layer includes any one of Ti, Mn, Cr, or Au.

(3)

In the solid-state imaging device according to (1) or (2), the antioxidant layer is a substance that is lower in hygroscopicity than the interlayer insulating film.

(4)

In the solid-state imaging device according to (3), the antioxidant layer is silicon nitride or aluminum oxide.

(5)

The solid-state imaging device according to any one of (1) to (4), further including a conducting layer provided in at least one of the first multilayer wiring layer or the second multilayer wiring layer so as to be exposed to a region of the bonding surface different from a region where the light shielding layer is exposed, the conducting layer being identical in material to the light shielding layer.

(6)

The solid-state imaging device according to any one of (1) to (5), further including an insulating layer provided in at least one of the first multilayer wiring layer or the second multilayer wiring layer so as to be exposed to the bonding surface, the insulating layer being different in material from the interlayer insulating film.

(7)

In the solid-state imaging device according to (6), the insulating layer is an oxide that is identical in material to the light shielding layer.

(8)

In the solid-state imaging device according to any one of (1) to (7),
the first semiconductor substrate includes a pixel region in which a plurality of the photoelectric conversion units is provided, and
the antioxidant layer is aligned with the pixel region in plan view.
   (9)

In the solid-state imaging device according to (8), an outline of the antioxidant layer in plan view is outside an outline of the pixel region in plan view.

(10)

In the solid-state imaging device according to any one of (1) to (9),
the antioxidant layer is provided in both the first multilayer wiring layer and the second multilayer wiring layer, and
the antioxidant layer provided in the first multilayer wiring layer and the antioxidant layer provided in the second multilayer wiring layer have portions aligned with each other in plan view.
   (11)

In the solid-state imaging device according to any one of (1) to (10),
the antioxidant layer is provided in both the first multilayer wiring layer and the second multilayer wiring layer, and
the antioxidant layer provided in the first multilayer wiring layer and the antioxidant layer provided in the second multilayer wiring layer have portions misaligned with each other in plan view.
   (12)

In the solid-state imaging device according to any one of (1) to (11),
the antioxidant layer is provided in both the first multilayer wiring layer and the second multilayer wiring layer, and
the antioxidant layer provided in the first multilayer wiring layer and the antioxidant layer provided in the second multilayer wiring layer are alternately provided along a direction orthogonal to a thickness direction.
   (13)

In the solid-state imaging device according to any one of (1) to (11),
the light shielding layer includes a first light shielding layer separated from the interlayer insulating film of the first semiconductor substrate by the antioxidant layer provided in the first multilayer wiring layer, and a second light shielding layer separated from the interlayer insulating film of the second semiconductor substrate by the antioxidant layer provided in the second multilayer wiring layer, and
the first light shielding layer and the second light shielding layer have portions out of contact with each other in a thickness direction.
   (14)

The solid-state imaging device according to any one of (1) to (13), further including:
a first connecting pad provided in the first multilayer wiring layer of the first semiconductor substrate;
a second connecting pad provided in the second multilayer wiring layer of the second semiconductor substrate, the second connecting pad being electrically connected to the first connecting pad; and
a gap i7n contact with both the first connecting pad and the second connecting pad.
   (15)

A solid-state imaging device including:
a first wiring layer including a first wiring and a first interlayer insulating film and
a second wiring layer including a second wiring and a second interlayer insulating film,
the first wiring layer and the second wiring layer being arranged to cause a first surface of the first wiring layer and a second surface of the second wiring layer to face each other,
the first surface including a first region, a second region, and a third region;
a first insulating film provided in the first region, the first insulating film being different from the first interlayer insulating film;
a first metal film provided in the second region, the first metal film being in contact with the first wiring; and
a second metal film provided in the third region, the second metal film being in contact with a second insulating film different from the first insulating film and the first interlayer insulating film.
   (16)

The solid-state imaging device according to (15), further including a semiconductor layer disposed in contact with the first wiring layer, the semiconductor layer including a photoelectric conversion unit or a logic circuit.

(17)

The solid-state imaging device according to (15) or (16), further including:
with the second surface including a fourth region, a fifth region, and a sixth region,
a third insulating film provided in the fourth region, the third insulating film being different from the second interlayer insulating film;
a third metal film provided in the fifth region, the third metal film being in contact with the second wiring; and
a fourth metal film provided in the sixth region, the fourth metal film being in contact with a fourth insulating film different from the third insulating film and the second interlayer insulating film, in which
the first region, the second region, and the third region face the fourth region, the fifth region, and the sixth region, respectively.
   (18)

In the solid-state imaging device according to any one of (15) to (17), the first interlayer insulating film is in contact with the first wiring, the first insulating film, or the second insulating film.

(19)

A method for manufacturing a solid-state imaging device including:
preparing a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface, and a second semiconductor substrate including a second semiconductor layer in which a circuit is formed and a second multilayer wiring layer including an interlayer insulating film formed on a side of the second semiconductor layer adjacent to the light incident surface;
forming an antioxidant layer in at least one of the interlayer insulating film of the first semiconductor substrate or the interlayer insulating film of the second semiconductor substrate;
forming a high melting point metal film on a surface of the first semiconductor substrate adjacent to the interlayer insulating film and a surface of the second semiconductor substrate adjacent to the interlayer insulating film;
bonding the high melting point metal film of the first semiconductor substrate and the high melting point metal film of the second semiconductor substrate to bond the first semiconductor substrate and the second semiconductor substrate together; and
performing heat treatment on the first semiconductor substrate and the second semiconductor substrate bonded together.
   (20)

An electronic instrument including:
a solid-state imaging device including a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface, a second semiconductor substrate including a second semiconductor layer in which a circuit is formed and a second multilayer wiring layer including an interlayer insulating film formed on a side of the second semiconductor layer adjacent to the light incident surface, the second multilayer wiring layer being bonded to the first multilayer wiring layer, a light shielding layer provided in at least one of the first multilayer wiring layer or the second multilayer wiring layer so as to be exposed to a bonding surface between the first multilayer wiring layer and the second multilayer wiring layer, and an antioxidant layer provided in at least one of the first multilayer wiring layer or the second multilayer wiring layer and provided at least either between the light shielding layer and the interlayer insulating film of the first multilayer wiring layer or between the light shielding layer and the interlayer insulating film of the second multilayer wiring layer;
an optical lens configured to form an image of image light from a subject on an imaging surface of the solid-state imaging device; and
a signal processing circuit configured to perform signal processing on a signal output from the solid-state imaging device.

The scope of the present technology is not limited to the illustrated and described exemplary embodiments, and includes all embodiments that provide effects equivalent to the effects intended to be provided by the present technology. Moreover, the scope of the present technology is not limited to the combinations of the features of the invention defined by the claims, and may be defined by any desired combination of specific features among all the recited features.

### REFERENCE SIGNS LIST

26 First semiconductor substrate
28 Second semiconductor substrate
31 Solid-state imaging device
31a, 34a, 71a, 76a, 86a Outline
34 Pixel region
36 First connecting wiring
36a, 58a Wiring groove
36b First connecting pad
53c First uppermost interlayer insulating film
56c Second uppermost interlayer insulating film
58 Second connecting wiring
58b Second connecting pad
70 Antioxidant film
71, 71E First antioxidant layer
72 Cu diffusion barrier metal film
74 Cu material layer
75 First high melting point metal film
76, 76D, 76E, 76E-1, 76E-2 Second antioxidant layer
77 Second high melting point metal film
78, 78A First insulating layer
79, 79A, 79C Second insulating layer
80, 80E First light shielding layer
81, 81E, 81E-1, 81E-2 Second light shielding layer
82 First conducting layer
83 Second conducting layer
84, 84A, 84B, 84C, 84D, 84E Bonding layer
85, 85A, 85B, 85C Insulating layer
86, 86B, 86C, 86D, 86E Light shielding layer
87, 87B Conducting layer
88, 89 Gap
90E Antioxidant layer formation region
201 Distance image device

1. A solid-state imaging device comprising:
a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface;
a second semiconductor substrate including a second semiconductor layer in which a circuit is formed and a second multilayer wiring layer including an interlayer insulating film formed on a side of the second semiconductor layer adjacent to the light incident surface, the second multilayer wiring layer being bonded to the first multilayer wiring layer;
a light shielding layer provided in at least one of the first multilayer wiring layer or the second multilayer wiring layer so as to be exposed to a bonding surface between the first multilayer wiring layer and the second multilayer wiring layer; and
an antioxidant layer provided in at least one of the first multilayer wiring layer or the second multilayer wiring layer and provided at least either between the light shielding layer and the interlayer insulating film of the first multilayer wiring layer or between the light shielding layer and the interlayer insulating film of the second multilayer wiring layer.

2. The solid-state imaging device according to claim 1, wherein the light shielding layer includes any one of Ti, Mn, Cr, or Au.

3. The solid-state imaging device according to claim 1, wherein the antioxidant layer is a substance that is lower in hygroscopicity than the interlayer insulating film.

4. The solid-state imaging device according to claim 3, wherein the antioxidant layer is silicon nitride or aluminum oxide.

5. The solid-state imaging device according to claim 1, further comprising a conducting layer provided in at least one of the first multilayer wiring layer or the second multilayer wiring layer so as to be exposed to a region of the bonding surface different from a region where the light shielding layer is exposed, the conducting layer being identical in material to the light shielding layer.

6. The solid-state imaging device according to claim 1, further comprising an insulating layer provided in at least one of the first multilayer wiring layer or the second multilayer wiring layer so as to be exposed to the bonding surface, the insulating layer being different in material from the interlayer insulating film.

7. The solid-state imaging device according to claim 6, wherein the insulating layer is an oxide that is identical in material to the light shielding layer.

8. The solid-state imaging device according to claim 1, wherein
the first semiconductor substrate includes a pixel region in which a plurality of the photoelectric conversion units is provided, and
the antioxidant layer is aligned with the pixel region in plan view.

9. The solid-state imaging device according to claim 8, wherein an outline of the antioxidant layer in plan view is outside an outline of the pixel region in plan view.

10. The solid-state imaging device according to claim 1, wherein
the antioxidant layer is provided in both the first multilayer wiring layer and the second multilayer wiring layer, and
the antioxidant layer provided in the first multilayer wiring layer and the antioxidant layer provided in the second multilayer wiring layer have portions aligned with each other in plan view.

11. The solid-state imaging device according to claim 1, wherein
the antioxidant layer is provided in both the first multilayer wiring layer and the second multilayer wiring layer, and
the antioxidant layer provided in the first multilayer wiring layer and the antioxidant layer provided in the second multilayer wiring layer have portions misaligned with each other in plan view.

12. The solid-state imaging device according to claim 1, wherein
the antioxidant layer is provided in both the first multilayer wiring layer and the second multilayer wiring layer, and
the antioxidant layer provided in the first multilayer wiring layer and the antioxidant layer provided in the second multilayer wiring layer are alternately provided along a direction orthogonal to a thickness direction.

13. The solid-state imaging device according to claim 1, wherein
the light shielding layer includes a first light shielding layer separated from the interlayer insulating film of the first semiconductor substrate by the antioxidant layer provided in the first multilayer wiring layer, and a second light shielding layer separated from the interlayer insulating film of the second semiconductor substrate by the antioxidant layer provided in the second multilayer wiring layer, and
the first light shielding layer and the second light shielding layer have portions out of contact with each other in a thickness direction.

14. The solid-state imaging device according to claim 1, further comprising:
a first connecting pad provided in the first multilayer wiring layer of the first semiconductor substrate;
a second connecting pad provided in the second multilayer wiring layer of the second semiconductor substrate, the second connecting pad being electrically connected to the first connecting pad; and
a gap in contact with both the first connecting pad and the second connecting pad.

15. A solid-state imaging device comprising:
a first wiring layer including a first wiring and a first interlayer insulating film and
a second wiring layer including a second wiring and a second interlayer insulating film,
the first wiring layer and the second wiring layer being arranged to cause a first surface of the first wiring layer and a second surface of the second wiring layer to face each other,
the first surface including a first region, a second region, and a third region;
a first insulating film provided in the first region, the first insulating film being different from the first interlayer insulating film;
a first metal film provided in the second region, the first metal film being in contact with the first wiring; and
a second metal film provided in the third region, the second metal film being in contact with a second insulating film different from the first insulating film and the first interlayer insulating film.

16. The solid-state imaging device according to claim 15, further comprising a semiconductor layer disposed in contact with the first wiring layer, the semiconductor layer including a photoelectric conversion unit or a logic circuit.

17. The solid-state imaging device according to claim 15, further comprising:
with the second surface including a fourth region, a fifth region, and a sixth region,
a third insulating film provided in the fourth region, the third insulating film being different from the second interlayer insulating film;
a third metal film provided in the fifth region, the third metal film being in contact with the second wiring; and
a fourth metal film provided in the sixth region, the fourth metal film being in contact with a fourth insulating film different from the third insulating film and the second interlayer insulating film, wherein
the first region, the second region, and the third region face the fourth region, the fifth region, and the sixth region, respectively.

18. The solid-state imaging device according to claim 15, wherein
the first interlayer insulating film is in contact with the first wiring, the first insulating film, or the second insulating film.

19. A method for manufacturing a solid-state imaging device comprising:
preparing a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface, and a second semiconductor substrate including a second semiconductor layer in which a circuit is formed and a second multilayer wiring layer including an interlayer insulating film formed on a side of the second semiconductor layer adjacent to the light incident surface;
forming an antioxidant layer in at least one of the interlayer insulating film of the first semiconductor substrate or the interlayer insulating film of the second semiconductor substrate;
forming a high melting point metal film on a surface of the first semiconductor substrate adjacent to the interlayer insulating film and a surface of the second semiconductor substrate adjacent to the interlayer insulating film;
bonding the high melting point metal film of the first semiconductor substrate and the high melting point metal film of the second semiconductor substrate to bond the first semiconductor substrate and the second semiconductor substrate together; and
performing heat treatment on the first semiconductor substrate and the second semiconductor substrate bonded together.

20. An electronic instrument comprising:
a solid-state imaging device including a first semiconductor substrate including a first semiconductor layer in which a photoelectric conversion unit configured to perform photoelectric conversion is formed, and a first multilayer wiring layer including an interlayer insulating film formed on a side of the first semiconductor layer remote from a light incident surface, a second semiconductor substrate including a second semiconductor layer in which a circuit is formed and a second multilayer wiring layer including an interlayer insulating film formed on a side of the second semiconductor layer adjacent to the light incident surface, the second multilayer wiring layer being bonded to the first multilayer wiring layer, a light shielding layer provided in at least one of the first multilayer wiring layer or the second multilayer wiring layer so as to be exposed to a bonding surface between the first multilayer wiring layer and the second multilayer wiring layer, and an antioxidant layer provided in at least one of the first multilayer wiring layer or the second multilayer wiring layer and provided at least either between the light shielding layer and the interlayer insulating film of the first multilayer wiring layer or between the light shielding layer and the interlayer insulating film of the second multilayer wiring layer;
an optical lens configured to form an image of image light from a subject on an imaging surface of the solid-state imaging device; and
a signal processing circuit configured to perform signal processing on a signal output from the solid-state imaging device.
